(19) United States
(12) Patent Application Publication
(10) Pub. No.: US 2025/0109491 A1
(43) Pub. Date: Apr. 3, 2025

(54) SELECTIVE DEPOSITION OF INHIBITOR MATERIAL AND DEPOSITION ASSEMBLIES

(71) Applicant: ASM IP Holding B.V., Almere (NL)

(72) Inventors: Eric James Shero, Phoenix, AZ (US); Marko Tuominen, Helsinki (FI); Saima Ali, Helsinki (FI); Bhagyesh Purohit, Helsinki (FI); Eva E. Tois, Espoo (FI); Kizysztof Kamil Kachel, Chandler, AZ (US); Adam Vianna, Phoenix, AZ (US); Vincent Vandalon, Heverlee (BE); Charles Dezelah, Helsinki (FI)

(21) Appl. No.: 18/900,571

(22) Filed: Sep. 27, 2024

Related U.S. Application Data
(60) Provisional application No. 63/586,830, filed on Sep. 29, 2023.

(51) Int. Cl. C23C 16/04

(52) U.S. Cl. CPC C23C 16/042

(57) ABSTRACT

The disclosure relates to methods, processing assemblies, reactants and vapor deposition vessels for selective vapor-phase deposition of inhibitor material on a substrate comprising two surfaces. In some embodiments of the disclosure, the inhibition material is deposited on the first surface of the substrate, whereas substantially no inhibitor material is deposited on the second surface of the substrate. The inhibitor material is formed by contacting the substrate with a vapor-phase inhibitor reactant comprising a silicon atom bonded to an oxygen atom and to a second atom selected from nitrogen and halogens.

### CROSS-REFERENCE TO RELATED APPLICATION(S)

This application claims the benefit of U.S. Provisional Application 63/586,830 filed on Sep. 29, 2023, the entire contents of which are incorporated herein by reference.

### FIELD

The present disclosure generally relates to methods and assemblies selectively depositing materials on substrates. Such methods may be used for, for example, processing semiconductor substrates. More particularly, the disclosure relates to methods and assemblies for selectively depositing an inhibitor material on a substrate, and to methods of depositing target materials.

### BACKGROUND

Semiconductor device fabrication processes generally use advanced vapor deposition methods. Patterning is conventionally used in depositing different materials on semiconductor substrates. Selective deposition, which is receiving increasing interest among semiconductor manufacturers, could enable a decrease in steps needed for conventional patterning, reducing the cost of processing. Selective deposition could also allow enhanced scaling in narrow structures. Various alternatives for bringing about selective deposition have been proposed, and additional improvements are needed to expand the use of selective deposition in industrial-scale device manufacturing.

Various materials, such as metal oxides, metal nitrides, elemental metals and silicon-containing materials, for example silicon oxide, silicon nitride and such materials combined with additional elements such as carbon, may be used for various purposes in semiconductor devices. The ability to choose the deposition surface between dielectric materials and conductive materials, such as metals or conductive metal nitrides, can simplify device fabrication process flows, and thus allow the deposition of more sensitive materials, possibly more accurately, as the need for patterning and etching steps may be reduced. Thermal deposition methods may be preferred over plasma-enhanced methods, due to better compatibility with sensitive materials. However, advanced semiconductor manufacturing techniques may combine thermal and plasma-enhanced deposition, as well steps utilizing plasma in optimizing the deposition process.

Any discussion, including discussion of problems and solutions, set forth in this section has been included in this disclosure solely for the purpose of providing a context for the present disclosure. Such discussion should not be taken as an admission that any of the information was known at the time the subject-matter of the disclosure was conceived or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter. Various embodiments of the present disclosure relate to methods of depositing inhibitor material, passivation material and various target materials; and particularly selectively depositing inhibitor material, passivation material and various target materials. Embodiments of the current disclosure further relate to methods of fabricating semiconductor devices, and to semiconductor processing assemblies.

In one aspect, a method of selectively depositing inhibitor material on a first surface of a substrate relative to a second surface of the substrate is disclosed. The method comprises providing the substrate comprising the first surface and the second surface in a reaction chamber and contacting the substrate with a vapor-phase inhibitor reactant, the inhibitor reactant comprising a silicon atom bonded to a first atom and to a second atom. In the inhibitor reactant, the first atom is oxygen, and the second atom is selected from nitrogen and a halogen and the inhibitor reactant selectively forms inhibitor material on the first surface. An inhibitor material in the current disclosure means a substance reducing or preventing the deposition of an organic polymer. In some embodiments, an inhibitor material may reduce or prevent the deposition of a target material. Passivation material in the current disclosure means a substance reducing or preventing the deposition a target material.

In some embodiments, the first surface comprises dielectric material. In some embodiments, the dielectric material comprises silicon. In some embodiments, the first surface comprises material selected from a group consisting of SiO₂, SiN, SiC, SiOC, SiON, SiOCN, SiGe and combinations thereof. In some embodiments, the dielectric material on the first surface comprises a metal oxide or a metal nitride. In some embodiments, the dielectric material on the first surface is selected from aluminum oxide, hafnium oxide, zirconium oxide, aluminum nitride, tantalum nitride and combinations thereof.

In some embodiments, the second surface is an electrically conductive surface. In some embodiments, the second surface comprises a material selected from a group consisting of a metal, amorphous carbon, metal oxide and metal nitride. In some embodiments, the second surface comprises a transition metal. In some embodiments, the second surface comprises a metal selected from a group consisting of Ti, V, Nb, Ta, Cr, Mo, W, Mn, Fe, Co, Ni, Cu, Zn, Ru and Al. In some embodiments, the second surface comprises elemental metal.

In some embodiments, the first atom in the inhibitor reactant is oxygen of an alkoxy group. In some embodiments, the silicon atom is bonded to at least one alkoxy group. For clarity, the at least one alkoxy group is bonded to the silicon atom through oxygen (“alkoxy oxygen”).

In some embodiments, the silicon atom is bonded to at least two alkoxy oxygens. Thus, in some embodiments, the silicon atom is bonded to at least two oxygen atoms, and each oxygen atom is an oxygen of an alkoxy group.

In some embodiments, the second atom is a nitrogen atom of an amine group. In some embodiments, the amine group is a tertiary amine. In some embodiments, the second atom is a halogen selected from a group consisting of F, Cl, Br and I.

In some embodiments, the inhibitor reactant is represented by a formula Si(OR)ₐX_{b}R′_{c}, wherein each R is independently selected from linear, branched and cyclic C1 to C6 alkyls and phenyl, each R′ is independently selected from H, linear, branched and cyclic C1 to C6 alkyls and phenyl, X is selected from halogens or NR′₂, a is 1, 2 or 3; b is 1 or 2; c is 0, 1 or 2; and a+b+c=4.

In some embodiments, all R and R′ are C1 to C4 alkyls. In some embodiments, each R is methyl or ethyl. In some embodiments, all of R are methyl or ethyl. In some embodiments, all of R′ are methyl or ethyl. In some embodiments, all of R and R′ are methyl or ethyl.

In some embodiments, the inhibitor reactant is selected from a group consisting of Si(OMet)₃Cl, Si(OMet)₃Br, Si(OMet)₃I, Si(OMet)₂Cl₂, Si(OMet)₂Br₂, Si(OMet)₂I₂, Si(OEt)₃Cl, Si(OEt)₃Br, Si(OEt)₃I, Si(OEt)₂Cl₂, Si(OEt)₂Br₂, Si(OEt)₂I₂, Si(OMet)₃(NH₂), Si(OMet)₂(NH₂)₂, Si(OEt)₃(NH₂), Si(OEt)₂(NH₂)₂, Si(OMet)₃(NMet₂), Si(OMet)₂(NMet₂)₂, Si(OEt)₃(NMet₂), Si(OEt)₂(NMet₂)₂, Si(OMet)₃(NMetH), Si(OMet)₂(NMetH)₂, Si(OEt)₃(NMetH), Si(OEt)₂(NMetH)₂, Si(OMet)₃(NEt₂), Si(OMet)₂(NEt₂)₂, Si(OEt)₃(NEt₂) and Si(OEt)₂(NEt₂)₂.

In some embodiments, the deposition of inhibitor material is performed at a temperature of below 400° C. In some embodiments, the inhibitor material is deposited substantially only on the first surface and not on the second surface.

In one aspect, a method of selectively depositing an organic polymer on a second surface of a substrate relative to a first surface of the substrate is disclosed. The method comprises selectively depositing inhibitor material on the first surface of the substrate according to the current disclosure, and thereafter selectively depositing the organic polymer on the second surface. In some embodiments, the organic polymer comprises polyimide. In some embodiments, the organic polymer forms a passivation layer on the second surface. In some embodiments, depositing the inhibitor material and depositing the organic polymer are performed in the same reaction chamber.

In a further aspect, a method of selectively depositing a target material on a first surface of a substrate is disclosed. The method comprises selectively depositing inhibitor material on the first surface of the substrate according to the current disclosure before depositing the target material.

In some embodiments, the method further comprises depositing a passivation layer on the second surface of the substrate after selectively depositing inhibitor material on the first surface, and thereafter depositing the target material on the first surface.

In some embodiments, the inhibitor material is not removed before depositing the target material on the first surface.

In some embodiments, the target material is deposited by a cyclic deposition process.

In some embodiments, the target material is deposited by an ALD process.

In a yet further aspect, a semiconductor processing assembly for selectively depositing inhibitor material on a first surface of a substrate is disclosed. The assembly comprises one or more reaction chambers constructed and arranged to hold the substrate, a precursor injector system constructed and arranged to provide an inhibitor reactant into the reaction chamber in a vapor phase. The semiconductor processing assembly further comprises an inhibitor reactant source vessel constructed and arranged to contain the inhibitor reactant comprising a silicon atom bonded to a first atom and to a second atom; wherein the first atom is oxygen, and the second atom is selected from nitrogen and a halogen.

The semiconductor processing assembly is further constructed and arranged to provide the inhibitor reactant via the precursor injector system into the reaction chamber for selectively forming inhibitor material on the first surface of the substrate. In some embodiments, the semiconductor processing assembly according to the current disclosure further comprises one or more precursor source vessels, wherein the precursor injector system is constructed and arranged to provide one or more precursors from the one or more precursor source vessels into the reaction chamber in a vapor phase for depositing a target material on the substrate.

In a yet further aspect, a method of depositing silicon-containing material on a substrate is disclosed. The method comprises providing the substrate in a reaction chamber, contacting the substrate with a vapor-phase silicon reactant having a formula Si(OR)ₐX_{b}R′_{c}. In the formula, each R is independently selected from linear, branched and cyclic C1 to C6 alkyls and phenyl, each R′ is independently selected from H, linear, branched and cyclic C1 to C6 alkyls and phenyl, X is selected from NR′₂, a is 1, 2 or 3; b is 1 or 2; c is 0, 1 or 2; and a+b+c=4. The silicon reactant forms silicon-containing material on the surface. In some embodiments, the silicon-containing material is an inhibitor. An inhibitor according to the current disclosure means a substance on a surface of a substrate reducing or inhibiting the deposition of a target material. In some embodiments, the silicon-containing material has a silicon to oxygen ratio from about 1:1 to 1:3. In some embodiments, the silicon-containing material is not subjected to oxidation. In some embodiments, the silicon-containing material is not contacted with an oxygen precursor.

In a yet further aspect, a vapor deposition vessel comprising an inhibitor reactant having a formula Si(OR)ₐX_{b}R′_{c}, is disclosed. In the formula, each R is independently selected from linear, branched and cyclic C1 to C6 alkyls and phenyl, each R′ is independently selected from H, linear, branched and cyclic C1 to C6 alkyls and phenyl, X is selected from NR′₂, a is 1, 2 or 3; b is 1 or 2; c is 0, 1 or 2; and a+b+c=4.

### BRIEF DESCRIPTION OF DRAWINGS

The accompanying drawings, which are included to provide a further understanding of the disclosure and constitute a part of this specification, illustrate exemplary embodiments, and together with the description help to explain the principles of the disclosure.

FIG. 1 is a block diagram of an exemplary embodiment of a method of selectively depositing inhibitor material according to the current disclosure.

FIG. 2 is a block diagram of an exemplary embodiment of a method of selectively depositing an organic polymer according to the current disclosure.

FIG. 3 is a block diagram of an exemplary embodiment of a method of selectively depositing a target material according to the current disclosure.

FIG. 4 is a schematic presentation of exemplary embodiments of methods according to the current disclosure.

FIG. 5 is a schematic drawing of an embodiment of a semiconductor processing assembly according to the current disclosure.

It will be appreciated that elements in the figures are illustrated for simplicity and clarity, and have not necessarily been drawn to scale. The illustrations presented herein are not meant to be actual views of any particular layer, structure, device or a processing assembly, but are merely idealized representations that are used to describe embodiments of the disclosure. For example, the dimensions of some of the elements in the figures may be exaggerated relative to other elements to help improve understanding of illustrated embodiments of the present disclosure.

### DETAILED DESCRIPTION

The description of exemplary embodiments of methods, layers, structures, devices, reactants and semiconductor processing assemblies provided below is merely exemplary and is intended for purposes of illustration only. The following description is not intended to limit the scope of the disclosure or the claims. Moreover, recitation of multiple embodiments having indicated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

The headings provided herein, if any, are for convenience only and do not necessarily affect the scope or meaning of the claimed subject-matter.

In one aspect, a method of selectively depositing inhibitor material on a first surface of a substrate relative to a second surface of the substrate is disclosed. The method comprises providing the substrate comprising the first surface and the second surface in a reaction chamber and contacting the substrate with a vapor-phase inhibitor reactant, the inhibitor reactant comprising a silicon atom bonded to a first atom and to a second atom. In the inhibitor reactant, the first atom is oxygen, and the second atom is selected from nitrogen and a halogen, and the inhibitor reactant selectively forms inhibitor material on the first surface.

As used herein, the term “layer” and/or “film” can refer to any continuous or non-continuous material, such as material deposited by the methods disclosed herein. For example, layer and/or film can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. In some embodiments, a layer according to the current disclosure is substantially continuous. In some embodiments, a layer according to the current disclosure is continuous.

In this disclosure, “gas” can include material that is a gas at normal temperature and pressure (NTP), a vaporized solid and/or a vaporized liquid, and can be constituted by a single gas or a mixture of gases, depending on the context. Reactants and precursors according to the current disclosure may be provided to the reaction chamber in gas phase. The term “inert gas” can refer to a gas that does not take part in a chemical reaction and/or does not become a part of a layer to an appreciable extent. Exemplary inert gases include He and Ar and any combination thereof. In some cases, molecular nitrogen and/or hydrogen can be an inert gas. A gas other than a process gas, i.e., a gas introduced without passing through a precursor injector system, other gas distribution device, or the like, can be used for, e.g., sealing the reaction chamber, and can include a seal gas.

The term dielectric is used in the description herein for the sake of simplicity in distinguishing from metal or metallic surfaces. It will be understood by those skilled in the art that not all non-conducting surfaces are dielectric surfaces. For example, the metal or metallic surface may comprise an oxidized metal surface that is electrically non-conducting or has a very high resistivity. Selective deposition processes of inhibitor material taught herein can deposit on dielectric surfaces with minimal deposition on such adjacent non-conductive metal or metallic surfaces.

The terms “precursor” and “reactant” can refer to molecules (compounds or molecules comprising a single element) that participate in a chemical reaction that produces another compound or an element. A precursor typically contains portions that are at least partly incorporated into the compound or element resulting from the chemical reaction in question. Such a resulting compound or element may be deposited on a substrate. In some instances, a reactant is a precursor. A reactant may also be a molecule that binds, such as chemisorbs, on the surface of a substrate without undergoing further chemical reactions at the surface with additional precursors and/or reactants. A reactant on a substrate surface may be modified by, for example, thermal or a plasma treatment.

In some embodiments, a precursor or a reactant is provided in a mixture of two or more compounds. In a mixture, the other compounds in addition to the precursor may be inert compounds or elements. In some embodiments, a precursor or a reactant is provided in a composition. Composition may be a solution or a gas in standard conditions.

As used herein, the term “comprising” indicates that certain features are included, but that it does not exclude the presence of other features, as long as they do not render the claim unworkable. In some embodiments, the term “comprising” includes “consisting.”

As used herein, the term “consisting” indicates that no further features are present in the apparatus/method/product apart from the ones following said wording. When the term “consisting” is used referring to a chemical compound, substance, or composition of matter, it indicates that the chemical compound, substance, or composition of matter only contains the components which are listed. Likewise, when the term “consisting essentially” is used referring to a chemical compound, substance, or composition of matter, it indicates that the chemical compound, substance, or composition of matter contains the components which are listed but can also containing trace elements and/or impurities that do not materially affect the characteristics of said chemical compound, substrate, or composition of matter. This notwithstanding, the chemical compound, substance, or composition of matter may, in some embodiments, comprise other components as trace elements or impurities, apart from the components that are listed.

Further, in this disclosure, any two numbers of a variable can constitute a workable range of the variable, and any ranges indicated may include or exclude the endpoints.

Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

### Substrate

The deposition method according to the current disclosure comprises providing a substrate in a reaction chamber. The substrate may be any underlying material or materials that can be used to form, or upon which, a structure, a device, a circuit, or a layer can be formed. A substrate can include a bulk material, such as silicon (e.g., single-crystal silicon), other Group IV materials, such as germanium, or other semiconductor materials, such as a Group II-VI or Group III-V semiconductor materials, and can include one or more layers overlying or underlying the bulk material. Further, the substrate can include various features, such as recesses, protrusions, and the like formed within or on at least a portion of a layer of the substrate. For example, a substrate can include bulk semiconductor material and an insulating or dielectric material layer overlying at least a portion of the bulk semiconductor material. Substrate may include nitrides, for example TiN, oxides, insulating materials, dielectric materials, conductive materials, metals, such as such as tungsten, ruthenium, molybdenum, cobalt, aluminum or copper, or metallic materials, crystalline materials, epitaxial, heteroepitaxial, and/or single crystal materials. In some embodiments of the current disclosure, the substrate comprises silicon. The substrate may comprise other materials, as described above, in addition to silicon. The other materials may form layers. Specifically, the substrate may comprise a partially fabricated semiconductor device.

A substrate according to the current disclosure comprises a first surface and a second surface. The first surface and the second surface have different material properties, allowing for the selective deposition of an inhibitor material on the first surface and optionally an organic polymer on the second surface. In some embodiments, the first surface and the second surface are adjacent to each other. In some embodiments, the first surface and the second surface are on the same face of a silicon wafer.

In some embodiments, the substrate may be pretreated or cleaned prior to or at the beginning of the selective deposition process according to the current disclosure. In some embodiments, the substrate may be subjected to a plasma cleaning process at prior to or at the beginning of the selective deposition process. In some embodiments, a plasma cleaning process may not include ion bombardment, or may include relatively small amounts of ion bombardment. For example, in some embodiments, the substrate surface may be exposed to plasma, radicals, excited species, and/or atomic species prior to or at the beginning of the selective deposition process. In some embodiments, the substrate surface may be exposed to hydrogen plasma, radicals, or atomic species prior to or at the beginning of the selective deposition process. In some embodiments, a pretreatment or cleaning process may be carried out in the same reaction chamber as a selective deposition process. However, in some embodiments, a pretreatment or cleaning process may be carried out in a separate reaction chamber.

### Reaction Chamber

The method of depositing inhibitor material according to the current disclosure comprises providing a substrate in a reaction chamber. In other words, a substrate is in a space where the deposition conditions can be controlled. The reaction chamber may be a single wafer reactor. Alternatively, the reaction chamber may be a batch reactor. The reaction chamber can form part of a vapor processing assembly for manufacturing semiconductor devices, such as a semiconductor processing assembly. The semiconductor processing assembly may comprise one or more multi-station processing chambers. The reaction chamber may be part of a cluster tool in which different processes are performed to form an integrated circuit. Various phases of the methods according to the current disclosure, such as methods of depositing an organic polymer, or methods of depositing a target material, can be performed within a single reaction chamber, or they can be performed in multiple reaction chambers, such as reaction chambers of a cluster tool, or deposition stations of a multi-station processing chamber.

In some embodiments, the reaction chamber may be a flow-type reactor, such as a cross-flow reactor. In some embodiments, the reaction chamber may be a showerhead reactor. In some embodiments, the reaction chamber may be a hot-wall reactor. In some embodiments, the reaction chamber may be a space-divided reactor. In some embodiments, the reaction chamber may be a single-wafer ALD reactor. In some embodiments, the reaction chamber may be a high-volume manufacturing single-wafer ALD reactor. In some embodiments, the reaction chamber may be a batch reactor for manufacturing multiple substrates simultaneously.

The reaction chamber of the current disclosure can form part of an atomic layer deposition (ALD) assembly. The reaction chamber can form part of a chemical vapor deposition (CVD) assembly. The processing assembly may be an ALD or a CVD processing assembly. In some parts of the deposition process flow, particularly if an organic polymer is deposited, molecular layer deposition (MLD) may be employed. In some embodiments, the method is performed in a single reaction chamber of a cluster tool, but other, preceding or subsequent, manufacturing steps of the structure or device are performed in additional reaction chambers of the same cluster tool. Optionally, a semiconductor processing assembly including the reaction chamber can be provided with a heater to activate the reactions by elevating the temperature of one or more of the substrate and/or the reactants and/or precursors.

### Cyclic Vapor Deposition

In some methods according to the current disclosure, particularly those of depositing an organic polymer, and a target material, cyclic vapor deposition methods may be used. Cyclic deposition in the current disclosure refers to vapor deposition processes in which deposition cycles, typically a plurality of consecutive deposition cycles, are conducted in a process chamber. For clarity, the deposition of inhibitor material according to the current disclosure may be a non-cyclic process, in which the inhibitor reactant is provided into the reaction chamber continuously. The inhibitor reactant may be provided into the reaction chamber in pulses.

Generally, in cyclic deposition processes according to the current disclosure, such as atomic layer deposition (ALD) and molecular layer deposition (MLD), during each cycle, a precursor is introduced to a reaction chamber and is chemisorbed to a substrate surface (e.g., a substrate surface that may include a previously deposited material from a previous deposition cycle or other material). In some embodiments, the precursor on the substrate surface does not readily react with additional precursor (i.e., the deposition of the precursor may be a partially or fully self-limiting reaction). Thereafter, another precursor or a reactant may be introduced into the reaction chamber for use in converting the chemisorbed precursor to the desired material on the deposition surface. The second precursor or a reactant can be capable of further reaction with the precursor. Purging steps may be utilized during one or more cycles, e.g., during each step of each cycle, to remove any excess precursor from the process chamber and/or remove any excess reactant and/or reaction byproducts from the reaction chamber. Thus, in some embodiments, the cyclic deposition process comprises purging the reaction chamber after providing a precursor into the reaction chamber. Without limiting the current disclosure to any specific theory, ALD and MLD may be similar processes in terms of self-limiting reactions and slower and more controllable layer growth speed compared to CVD. Generally, ALD is used to deposit inorganic materials, such as a dielectric material, a metal oxide, a metal nitride or an elemental metal, whereas in MLD, the precursors may be fully organic molecules, such as when an organic polymer is deposited.

In some embodiments, the process according to the current disclosure may contain a CVD component. CVD-type processes may be characterized by vapor deposition which is not self-limiting. They typically involve gas phase reactions between two or more precursors and/or reactants. The precursor(s) and reactant(s) can be provided simultaneously to the reaction chamber or substrate, or in partially or completely separated pulses. However, CVD may be performed with a single precursor, or two or more precursors that do not react with each other. A single precursor may decompose into reactive components that are deposited on the substrate surface. The decomposition may be brought about by plasma or thermal means, for example. The substrate and/or reaction chamber can be heated to promote the reaction between the gaseous precursor and/or reactants. In some embodiments the precursor(s) and reactant(s) are provided until a layer having a desired thickness is deposited. In some embodiments, cyclic CVD processes can be used with multiple cycles to deposit a thin film having a desired thickness. In cyclic CVD processes, the precursors and/or reactants may be provided to the reaction chamber in pulses that do not overlap, or that partially or completely overlap. The process may comprise one or more cyclic phases. In some embodiments, the process comprises or one or more non-cyclic (i.e. continuous) phases. An example of a continuous phase could be a pre-treatment with a single reactant. In some embodiments, the deposition process comprises the continuous flow of at least one precursor. In some embodiments, one or more of the precursors are provided in the reaction chamber continuously.

In some embodiments, the inhibitor material according to the current disclosure is deposited at a pressure of at least 0.01 Torr to at most about 760 Torr, or at a pressure of at least 0.1 Torr to at most 150 Torr, or at a pressure of at least 0.5 Torr to at most 25 Torr, or at a pressure of at least 1 Torr to at most 10 Torr, or at a pressure of at least 2 Torr to at most 5 Torr. For example, the inhibitor material may be deposited at a pressure of about 1 Torr, about 2 Torr, about 3 Torr, about 5 Torr, about 6 Torr, about 8 Torr, about 9 Torr, about 12 Torr or about 18 Torr. In some embodiments, further processing steps are performed at the same pressure. In some embodiments, further processing steps are performed at a different pressure, which may be lower or higher than the pressure at which the inhibitor material is deposited.

In some embodiments, the cyclic vapor deposition processes according to the current disclosure comprises a thermal deposition process. In thermal deposition, the chemical reactions are promoted by increased temperature relevant to ambient temperature. Generally, temperature increase provides the energy needed for the formation of the target material in the absence of other external energy sources, such as plasma, radicals, or other forms of radiation. However, in some embodiments, the methods according to the current disclosure, especially methods of depositing a target material, comprise a plasma-enhanced deposition method, for example PEALD or PECVD. In some embodiments, an inhibitor material deposition may be performed by PEALD or PECVD.

### Selectivity

The current disclosure relates to selective deposition processes. When material is formed or deposited selectively on a first surface of the substrate relative to a second surface of the substrate, selectivity can be given as a percentage calculated by [(deposition on first surface)−(deposition on second surface)]/(deposition on the first surface). When organic polymer material is deposited on the second surface, the calculation is reversed accordingly.

In some embodiments, selectivity is at least about 30%. In some embodiments, selectivity is at least about 50%. In some embodiments, selectivity is at least about 75% or greater than about 85%. In some embodiments, selectivity is at least about 90% or at least about 93%. In some embodiments, selectivity is at least about 95% or at least about 98%. In some embodiments, selectivity is at least about 99% or even at least about 99.5%. In embodiments, the selectivity can change over the duration or thickness of a deposition.

Deposition can be measured in any of a variety of ways. In some embodiments, deposition may be given as the measured thickness of the deposited material. In some embodiments, deposition may be given as the measured amount of deposited material.

Sometimes selectivity, for example after treating one of at least two surfaces of a substrate with an inhibitor, may be measured as nucleation delay expressed as number of deposition cycles before target material growth is observed on the different surfaces. In such cases, the term “selectivity window” can be used to describe the difference between the number of cycles on the different surfaces before growth of a target material is observed.

In some embodiments, the inhibitor material is deposited substantially only on the first surface and not on the second surface. Thus, deposition of the inhibitor material only occurs on one surface, such as the first surface, and does substantially not occur on the other surface(s). In some embodiments, deposition on the first surface of the substrate relative to the second surface of the substrate is at least about 80% selective, which may be selective enough for some particular applications. In some embodiments the deposition on the first surface of the substrate relative to the second surface of the substrate is at least about 50% selective, which may be selective enough for some particular applications. In some embodiments the deposition on the first surface of the substrate relative to the second surface of the substrate is at least about 10% selective, which may be selective enough for some particular applications.

In some embodiments, selective deposition of the inhibitor material is inherent, and no preceding or additional processing steps over those conveniently performed on a substrate are necessary. Selectivity may be inherent to a certain thickness of deposited material, and be lost in case deposition is continued beyond a process-specific threshold. If thicker material layers are desired, the contrast between the first surface and the second surface may be enhanced though, for example, intermittent etch-back phase. Plasma, such as hydrogen plasma, may be used.

### Inhibitor Reactant

In the methods according to the current disclosure, the substrate is contacted with a vapor-phase inhibitor reactant. Thus, the inhibitor reactant is gaseous when it contacts the substrate. In some applications, such as spin-coating, a liquid inhibitor reactant may be used.

The inhibitor reactant comprises a silicon atom bonded to a first atom and to a second atom. In the inhibitor reactant, the first atom is oxygen, and the second atom is selected from nitrogen and a halogen. In some embodiments, the inhibitor reactant comprises one silicon atom. In some embodiments, the inhibitor reactant comprises one silicon atom and the silicon atom is bonded to one oxygen atom. In some embodiments, the inhibitor reactant comprises one silicon atom and the silicon atom is bonded to two oxygen atoms. In some embodiments, the inhibitor reactant comprises one silicon atom and the silicon atom is bonded to three oxygen atoms.

In some embodiments, the first atom in the inhibitor reactant is oxygen of an alkoxy group. Thus, in some embodiments, the silicon atom is bonded to at least one alkoxy group. The at least one alkoxy group is bonded to the silicon atom through oxygen (the “alkoxy oxygen”). In some embodiments, the silicon atom is bonded to two alkoxy groups. In some embodiments, the silicon atom is bonded to three alkoxy groups. An alkoxy group according to the current disclosure comprises an oxygen atom bonded to a C1 to C6 alkyl or a phenyl group. Thus, the alkyl group may be aliphatic or aromatic. The alkyl group may be saturated or unsaturated, linear or branched, cyclic or acyclic. In some embodiments, the alkyl group is an unsubstituted hydrocarbon, i.e. it comprises only carbon and hydrogen. In some embodiments, the silicon atom is bonded to at least two alkoxy oxygens.

The alkoxy group may be a C1 to C6 alkoxy group. In some embodiments, each of the alkoxy groups in the inhibitor reactant is selected from a group consisting of methoxy, ethoxy, n-propoxy, isopropoxy, n-butoxy, isobutoxy, sec-butoxy, tert-butoxy, n-pentoxy, 1,1-dimethylpropoxy, 3-methylbutoxy, 1-methylbutoxy, 2,2-dimethylpropoxy, 1-ethylpropoxy, 1,2-dimethylpropoxy and 2-methylbutoxy.

Each of the alkoxide groups bonded to the silicon atom can be independently selected. In some embodiments, the inhibitor reactant comprises two alkoxide groups that are the same. In some embodiments, the inhibitor reactant comprises two alkoxide groups that are different. In some embodiments, the inhibitor reactant comprises three alkoxide groups that are the same. In some embodiments, the inhibitor reactant comprises three alkoxide groups that are different. In some embodiments, the inhibitor reactant comprises three alkoxide groups, two of which are the same.

In some embodiments, the inhibitor reactant comprises one methoxy group. In some embodiments, the inhibitor reactant comprises two methoxy groups. In some embodiments, the inhibitor reactant comprises three methoxy groups. In some embodiments, the inhibitor reactant comprises one ethoxy group. In some embodiments, the inhibitor reactant comprises two ethoxy groups. In some embodiments, the inhibitor reactant comprises three ethoxy groups. In some embodiments, the inhibitor reactant comprises one propoxy group. In some embodiments, the inhibitor reactant comprises two propoxy groups. In some embodiments, the inhibitor reactant comprises three propoxy groups.

In some embodiments, the inhibitor reactant comprises one methoxy group and one ethoxy group. In some embodiments, the inhibitor reactant comprises one methoxy group and two ethoxy groups. In some embodiments, the inhibitor reactant comprises two methoxy groups and one ethoxy group. In some embodiments, the inhibitor reactant comprises one methoxy group and two propoxy groups. In some embodiments, the inhibitor reactant comprises two methoxy groups and one propoxy group. In some embodiments, the inhibitor reactant comprises one propoxy group and two ethoxy groups. In some embodiments, the inhibitor reactant comprises two propoxy groups and one ethoxy group.

In some embodiments, the second atom in the inhibitor reactant is a nitrogen atom of an amine group. In some embodiments, the amine group is a primary amine (—NH₂). In some embodiments, the amine group is a secondary amine (—NRH). In some embodiments, the amine group is a tertiary amine (—NR₂). For secondary and tertiary amines, the one or two alkyl or aryl groups can be selected from linear, branched and cyclic C1 to C6 alkyls and phenyl. In tertiary amines, the alkyl groups may be independently selected. Thus, the alkyl groups attached to the nitrogen atom may be the same or different. In some embodiments, the amine is dimethylamine. In some embodiments, the amine is diethylamine. In some embodiments, the amine is dipropylamine. In some embodiments, the amine is di-n-propylamine. In some embodiments, the amine is diisopropylamine. In some embodiments, the amine is dibutylamine. In some embodiments, the amine is di-n-butylamine. In some embodiments, the amine is di-sec-butylamine. In some embodiments, the amine is di-tert-butylamine. In some embodiments, the amine is diisobutylamine. In some embodiments, the amine is ethylmethylamine. In some embodiments, the amine is methylpropylamine. In some embodiments, the amine is ethylpropylamine.

In some embodiments, the second atom is a halogen selected from a group consisting of F, Cl, Br and I. In some embodiments, the second atom is a halogen selected from a group consisting of Cl, Br and I. In some embodiments, the second atom is a halogen selected from a group consisting of Cl and Br. In some embodiments, the second atom is a halogen selected from a group consisting of Cl and I. In some embodiments, the second atom is F. In some embodiments, the second atom is Cl. In some embodiments, the second atom is Br. In some embodiments, the second atom is I.

In addition to at least one alkoxy group and at least one N- or halogen-containing group, the inhibitor reactant may contain at least one additional atom bonded to the silicon atom. For example, an additional atom may be hydrogen (H) or carbon (C). The carbon atom may be bonded to further carbon atoms and/or hydrogen atoms. In other words, the silicon atom may be bonded to an alkyl group. For example, the inhibitor reactant may comprise two alkoxy groups, one amine group and one hydrogen or an alkyl bonded to a silicon atom. In another example, the inhibitor reactant may comprise one alkoxy group, two amine groups and one hydrogen or an alkyl bonded to a silicon atom. In some embodiments, the inhibitor reactant may comprise one alkoxy group, two halogens and one hydrogen or an alkyl bonded to a silicon atom. In some embodiments, the inhibitor reactant comprises two additional atoms attached to silicon atom. The additional alkyl bonded to the silicon atom may be selected from linear and branched C1 to C6 alkyls. In some embodiments, the alkyl group is selected from a group consisting of methyl (Met), ethyl (Et), n-propyl (Pr), isopropyl (ⁱPr), n-butyl (Bu), isobutyl (iBu), sec-butyl (sBu), tert-butyl (tBu), n-pentyl (Pe), tert-pentyl (tPe), neopentyl (nPe), isopentyl (iPe), sec-pentyl (sPe), 3-pentyl (2Pe), sec-isopentyl (siPe) and 2-methylbutyl (2-MetBu).

In some embodiments, the inhibitor reactant is represented by a formula Si(OR)ₐX_{b}R′_{c}, wherein each R is independently selected from linear, branched and cyclic C1 to C6 alkyls and phenyl, each R′ is independently selected from H, linear, branched and cyclic C1 to C6 alkyls and phenyl, X is selected from halogens or NR′₂, a is 1, 2 or 3; b is 1 or 2; c is 0, 1 or 2; and a+b+c=4.

In some embodiments, all R and R′ are C1 to C4 alkyls. In some embodiments, all of R are methyl or ethyl. In some embodiments, all of R′ are methyl or ethyl. In some embodiments, all of R and R′ are methyl or ethyl. In some embodiments, all of R are methyl. In some embodiments, all of R′ are methyl. In some embodiments, all of R and R′ are methyl. In some embodiments, all of R are ethyl. In some embodiments, all of R′ are ethyl. In some embodiments, all of R and R′ are ethyl.

In some embodiments, the inhibitor reactant comprises a halogen and is selected from a group consisting of Si(OMet)Met₂Cl, Si(OMet)₂MetCl, Si(OMet)₃Cl, Si(OMet)₂HCl, Si(OMet)H₂Cl, Si(OMet)Met₂Br, Si(OMet)₂MetBr, Si(OMet)₃Br, Si(OMet)₂HBr, Si(OMet)H₂Br, Si(OMet)Met₂I, Si(OMet)₂MetI, Si(OMet)₃I, Si(OMet)₂HI, Si(OMet)H₂I, Si(OMet)MetCl₂, Si(OMet)HCl₂, Si(OMet)₂Cl₂, Si(OMet)Cl₃, Si(OMet)MetBr₂, Si(OMet)HBr₂, Si(OMet)₂Br₂, Si(OMet)Br₃, Si(OMet)MetI₂, Si(OMet)HI₂, Si(OMet)₂I₂, Si(OMet)I₃, Si(OEt)Met₂Cl, Si(OEt)₂MetCl, Si(OEt)₃Cl, Si(OEt)₂HCl, Si(OEt)H₂Cl, Si(OEt)Met₂Br, Si(OEt)₂MetBr, Si(OEt)₃Br, Si(OEt)₂HBr, Si(OEt)H₂Br, Si(OEt)Met₂I, Si(OEt)₂MetI, Si(OEt)₃I, Si(OEt)₂HI, Si(OEt)H₂I, Si(OEt)MetCl₂, Si(OEt)HCl₂, Si(OEt)₂Cl₂, Si(OEt)Cl₃, Si(OEt)MetBr₂, Si(OEt)HBr₂, Si(OEt)₂Br₂, Si(OEt)Br₃, Si(OEt)MetI₂, Si(OEt)HI₂, Si(OEt)₂I₂, Si(OEt)I₃, Si(OMet)Et₂Cl, Si(OMet)₂EtCl, Si(OMet)Et₂Br, Si(OMet)₂EtBr, Si(OMet)Et₂I, Si(OMet)₂EtI, Si(OMet)EtCl₂, Si(OMet)EtBr₂, Si(OMet)EtI₂, Si(OEt)Et₂Cl, Si(OEt)₂EtCl, Si(OEt)Et₂Br, Si(OEt)₂EtBr, Si(OEt)Et₂I, Si(OEt)₂EtI, Si(OEt)EtCl₂, Si(OEt)EtBr₂, Si(OEt)EtI₂, Si(OPr)Met₂Cl, Si(OPr)₂MetCl, Si(OPr)₃Cl, Si(OPr)₂HCl, Si(OPr)H₂Cl, Si(OPr)Met₂Br, Si(OPr)₂MetBr, Si(OPr)₃Br, Si(OPr)₂HBr, Si(OPr)H₂Br, Si(OPr)Met₂I, Si(OPr)₂MetI, Si(OPr)₃I, Si(OPr)₂HI, Si(OPr)H₂I, Si(OPr)MetCl₂, Si(OPr)HCl₂, Si(OPr)₂Cl₂, Si(OPr)Cl₃, Si(OPr)MetBr₂, Si(OPr)HBr₂, Si(OPr)₂Br₂, Si(OPr)Br₃, Si(OPr)MetI₂, Si(OPr)HI₂, Si(OPr)₂I₂, Si(OPr)I₃, Si(OPr)Et₂Cl, Si(OPr)₂EtCl, Si(OPr)Et₂Br, Si(OPr)₂EtBr, Si(OPr)Et₂I, Si(OPr)₂EtI, Si(OPr)EtCl₂, Si(OPr)EtBr₂, Si(OPr)EtI₂, Si(OPr)Pr₂Cl, Si(OPr)₂PrCl, Si(OPr)Pr₂Br, Si(OPr)₂PrBr, Si(OPr)Pr₂I, Si(OPr)₂PrI, Si(OPr)PrCl₂, Si(OPr)PrBr₂, Si(OPr)PrI₂, Si(OⁱPr)Met₂Cl, Si(OⁱPr)₂MetCl, Si(OⁱPr)₃Cl, Si(OⁱPr)₂HCl, Si(OⁱPr)H₂Cl, Si(OⁱPr)Met₂Br, Si(OⁱPr)₂MetBr, Si(OⁱPr)₃Br, Si(OⁱPr)₂HBr, Si(OⁱPr)H₂Br, Si(OⁱPr)Met₂I, Si(OⁱPr)₂MetI, Si(OⁱPr)₃I, Si(OⁱPr)₂HI, Si(OⁱPr)H₂I, Si(OⁱPr)MetCl₂, Si(OⁱPr)HCl₂, Si(OⁱPr)₂Cl₂, Si(OⁱPr)Cl₃, Si(OⁱPr)MetBr₂, Si(OⁱPr)HBr₂, Si(OⁱPr)₂Br₂, Si(OⁱPr)Br₃, Si(OⁱPr)MetI₂, Si(OⁱPr)HI₂, Si(OⁱPr)₂I₂, Si(OⁱPr)I₃, Si(OⁱPr)Et₂Cl, Si(OⁱPr)₂EtCl, Si(OⁱPr)Et₂Br, Si(OⁱPr)₂EtBr, Si(OⁱPr)Et₂I, Si(OⁱPr)₂EtI, Si(OⁱPr)EtCl₂, Si(OⁱPr)EtBr₂, Si(OⁱPr)EtI₂, Si(OⁱPr)iPr₂Cl, Si(OⁱPr)₂′PrCl, Si(OⁱPr)iPr₂Br, Si(OⁱPr)₂′PrBr, Si(OⁱPr)ⁱPr₂I, Si(OⁱPr)₂iPrI, Si(OⁱPr)ⁱPrCl₂, Si(OⁱPr)ⁱPrBr₂, Si(OⁱPr)ⁱPrI₂, Si(OⁱPr)Pr₂Cl, Si(OⁱPr)₂PrCl, Si(OⁱPr)Pr₂Br, Si(OⁱPr)₂PrBr, Si(OⁱPr)Pr₂I, Si(OⁱPr)₂PrI, Si(OⁱPr)PrCl₂, Si(OⁱPr)PrBr₂ and Si(OⁱPr)PrI₂.

In some embodiment, the second atom in the inhibitor reactant is nitrogen of a primary amine group. In some embodiments, the primary amine group-containing inhibitor reactant is selected from a group consisting of Si(OMet)Met₂(NH₂), Si(OMet)₂Met(NH₂), Si(OMet)₃(NH₂), Si(OMet)₂H(NH₂), Si(OMet)H₂(NH₂), Si(OMet)Met(NH₂)₂, Si(OMet)H(NH₂)₂, Si(OMet)₂(NH₂)₂, Si(OMet)(NH₂)₃, Si(OEt)Met₂(NH₂), Si(OEt)₂Met(NH₂), Si(OEt)₃(NH₂), Si(OEt)₂H(NH₂), Si(OEt)H₂(NH₂), Si(OEt)Met(NH₂)₂, Si(OEt)H(NH₂)₂, Si(OEt)₂(NH₂)₂, Si(OEt)(NH₂)₃, Si(OMet)Et₂(NH₂), Si(OMet)₂Et(NH₂), Si(OMet)Et(NH₂)₂, Si(OEt)Et₂(NH₂), Si(OEt)₂Et(NH₂), Si(OEt)Et(NH₂)₂, Si(OPr)Met₂(NH₂), Si(OPr)₂Met(NH₂), Si(OPr)₃(NH₂), Si(OPr)₂H(NH₂), Si(OPr)H₂(NH₂), Si(OPr)Met(NH₂)₂, Si(OPr)H(NH₂)₂, Si(OPr)₂(NH₂)₂, Si(OPr)(NH₂)₃, Si(OPr)Et₂(NH₂), Si(OPr)₂Et(NH₂), Si(OPr)Et(NH₂)₂, Si(OPr)Pr₂(NH₂), Si(OPr)₂Pr(NH₂), Si(OPr)Pr(NH₂)₂, Si(OiPr)Met₂(NH₂), Si(OiPr)₂Met(NH₂), Si(OiPr)₃(NH₂), Si(OiPr)₂H(NH₂), Si(OiPr)H₂(NH₂), Si(OiPr)Met(NH₂)₂, Si(OiPr)H(NH₂)₂, Si(OiPr)₂(NH₂)₂, Si(OiPr)(NH₂)₃, Si(OiPr)Et₂(NH₂), Si(OiPr)₂Et(NH₂), Si(OiPr)Et(NH₂)₂, Si(OiPr)iPr₂(NH₂), Si(OiPr)₂iPr(NH₂), Si(OiPr)iPr(NH₂)₂, Si(OiPr)Pr₂(NH₂), Si(OiPr)₂Pr(NH₂) and Si(OiPr)Pr(NH₂)₂.

In some embodiments, the second atom is a nitrogen of an alkylamine group, i.e. a nitrogen atom of a secondary amine. In some embodiments, the inhibitor reactant is selected from a group consisting of Si(OMet)Met₂(NMetH), Si(OMet)₂Met(NMetH), Si(OMet)₃(NMetH), Si(OMet)₂H(NMetH), Si(OMet)H₂(NMetH), Si(OMet)Met(NMetH)₂, Si(OMet)H(NMetH)₂, Si(OMet)₂(NMetH)₂, Si(OMet)(NMetH)₃, Si(OEt)Met₂(NMetH), Si(OEt)₂Met(NMetH), Si(OEt)₃(NMetH), Si(OEt)₂H(NMetH), Si(OEt)H₂(NMetH), Si(OEt)Met(NMetH)₂, Si(OEt)H(NMetH)₂, Si(OEt)₂(NMetH)₂, Si(OEt)(NMetH)₃, Si(OMet)Et₂(NMetH), Si(OMet)₂Et(NMetH), Si(OMet)Et(NMetH)₂, Si(OEt)Et₂(NMetH), Si(OEt)₂Et(NMetH), Si(OEt)Et(NMetH)₂, Si(OPr)Met₂(NMetH), Si(OPr)₂Met(NMetH), Si(OPr)₃(NMetH), Si(OPr)₂H(NMetH), Si(OPr)H₂(NMetH), Si(OPr)Met(NMetH)₂, Si(OPr)H(NMetH)₂, Si(OPr)₂(NMetH)₂, Si(OPr)(NMetH)₃, Si(OPr)Et₂(NMetH), Si(OPr)₂Et(NMetH), Si(OPr)Et(NMetH)₂, Si(OPr)Pr₂(NMetH), Si(OPr)₂Pr(NMetH), Si(OPr)Pr(NMetH)₂, Si(OⁱPr)Met₂(NMetH), Si(OⁱPr)₂Met(NMetH), Si(OⁱPr)₃(NMetH), Si(OⁱPr)₂H(NMetH), Si(OⁱPr)H₂(NMetH), Si(OⁱPr)Met(NMetH)₂, Si(OⁱPr)H(NMetH)₂, Si(OⁱPr)₂(NMetH)₂, Si(OⁱPr)(NMetH)₃, Si(OⁱPr)Et₂(NMetH), Si(OⁱPr)₂Et(NMetH), Si(OⁱPr)Et(NMetH)₂, Si(OⁱPr)ⁱPr₂(NMetH), Si(OⁱPr)₂iPr(NMetH), Si(OⁱPr)ⁱPr(NMetH)₂, Si(OⁱPr)Pr₂(NMetH), Si(OⁱPr)₂Pr(NMetH), Si(OⁱPr)Pr(NMetH)₂, Si(OMet)Met₂(NEtH), Si(OMet)₂Met(NEtH), Si(OMet)₃(NEtH), Si(OMet)₂H(NEtH), Si(OMet)H₂(NEtH), Si(OMet)Met(NEtH)₂, Si(OMet)H(NEtH)₂, Si(OMet)₂(NEtH)₂, Si(OMet)(NEtH)₃, Si(OEt)Met₂(NEtH), Si(OEt)₂Met(NEtH), Si(OEt)₃(NEtH), Si(OEt)₂H(NEtH), Si(OEt)H₂(NEtH), Si(OEt)Met(NEtH)₂, Si(OEt)H(NEtH)₂, Si(OEt)₂(NEtH)₂, Si(OEt)(NEtH)₃, Si(OMet)Et₂(NEtH), Si(OMet)₂Et(NEtH), Si(OMet)Et(NEtH)₂, Si(OEt)Et₂(NEtH), Si(OEt)₂Et(NEtH), (OEt)H₂(NEtH), Si(OEt)Et(NEtH)₂, Si(OPr)Met₂(NEtH), Si(OPr)₂Met(NEtH), Si(OPr)₃(NEtH), Si(OPr)₂H(NEtH), Si(OPr)H₂(NEtH), Si(OPr)Met(NEtH)₂, Si(OPr)H(NEtH)₂, Si(OPr)₂(NEtH)₂, Si(OPr)(NEtH)₃, Si(OPr)Et₂(NEtH), Si(OPr)₂Et(NEtH), Si(OPr)Et(NEtH)₂, Si(OPr)Pr₂(NEtH), Si(OPr)₂Pr(NEtH), Si(OPr)Pr(NEtH)₂, Si(OⁱPr)Met₂(NEtH), Si(OⁱPr)₂Met(NEtH), Si(OⁱPr)₃(NEtH), Si(OⁱPr)₂H(NEtH), Si(OⁱPr)H₂(NEtH), Si(OⁱPr)Met(NEtH)₂, Si(OⁱPr)H(NEtH)₂, Si(OⁱPr)₂(NEtH)₂, Si(OⁱPr)(NEtH)₃, Si(OⁱPr)Et₂(NEtH), Si(OⁱPr)₂Et(NEtH), Si(OⁱPr)Et(NEtH)₂, Si(OⁱPr)ⁱPr₂(NEtH), Si(OⁱPr)₂′Pr(NEtH), Si(OⁱPr)ⁱPr(NEtH)₂, Si(OⁱPr)Pr₂(NEtH), Si(OⁱPr)₂Pr(NEtH), Si(OⁱPr)Pr(NEtH)₂, Si(OMet)Met₂(NPrH), Si(OMet)₂Met(NPrH), Si(OMet)₃(NPrH), Si(OMet)₂H(NPrH), Si(OMet)H₂(NPrH), Si(OMet)Met(NPrH)₂, Si(OMet)H(NPrH)₂, Si(OMet)₂(NPrH)₂, Si(OMet)(NPrH)₃, Si(OEt)Met₂(NPrH), Si(OEt)₂Met(NPrH), Si(OEt)₃(NPrH), Si(OEt)₂H(NPrH), Si(OEt)H₂(NPrH), Si(OEt)Met(NPrH)₂, Si(OEt)H(NPrH)₂, Si(OEt)₂(NPrH)₂, Si(OEt)(NPrH)₃, Si(OMet)Et₂(NPrH), Si(OMet)₂Et(NPrH), Si(OMet)Et(NPrH)₂, Si(OEt)Et₂(NPrH), Si(OEt)₂Et(NPrH), Si(OEt)Et(NPrH)₂, Si(OPr)Met₂(NPrH), Si(OPr)₂Met(NPrH), Si(OPr)₃(NPrH), Si(OPr)₂H(NPrH), Si(OPr)H₂(NPrH), Si(OPr)Met(NPrH)₂, Si(OPr)H(NPrH)₂, Si(OPr)₂(NPrH)₂, Si(OPr)(NPrH)₃, Si(OPr)Et₂(NPrH), Si(OPr)₂Et(NPrH), Si(OPr)Et(NPrH)₂, Si(OPr)Pr₂(NPrH), Si(OPr)₂Pr(NPrH), Si(OPr)Pr(NPrH)₂, Si(OⁱPr)Met₂(NPrH), Si(OⁱPr)₂Met(NPrH), Si(OⁱPr)₃(NPrH), Si(OⁱPr)₂H(NPrH), Si(OⁱPr)H₂(NPrH), Si(OⁱPr)Met(NPrH)₂, Si(OⁱPr)H(NPrH)₂, Si(OⁱPr)₂(NPrH)₂, Si(OⁱPr)(NPrH)₃, Si(OⁱPr)Et₂(NPrH), Si(OⁱPr)₂Et(NPrH), Si(OⁱPr)Et(NPrH)₂, Si(OⁱPr)ⁱPr₂(NPrH), Si(OⁱPr)₂′Pr(NPrH), Si(OⁱPr)ⁱPr(NPrH)₂, Si(OⁱPr)Pr₂(NPrH), Si(OⁱPr)₂Pr(NPrH), Si(OⁱPr)Pr(NPrH)₂, Si(OMet)Met₂(NⁱPrH), Si(OMet)₂Met(NⁱPrH), Si(OMet)₃(NⁱPrH), Si(OMet)₂H(NⁱPrH), Si(OMet)H₂(NⁱPrH), Si(OMet)Met(NⁱPrH)₂, Si(OMet)H(NⁱPrH)₂, Si(OMet)₂(NⁱPrH)₂, Si(OMet)(NⁱPrH)₃, Si(OEt)Met₂(NⁱPrH), Si(OEt)₂Met(NⁱPrH), Si(OEt)₃(NⁱPrH), Si(OEt)₂H(NⁱPrH), Si(OEt)H₂(NⁱPrH), Si(OEt)Met(NⁱPrH)₂, Si(OEt)H(NⁱPrH)₂, Si(OEt)₂(NⁱPrH)₂, Si(OEt)(NⁱPrH)₃, Si(OMet)Et₂(NⁱPrH), Si(OMet)₂Et(NⁱPrH), (OMet)Et(NⁱPrH)₂, Si(OEt)Et₂(NⁱPrH), Si(OEt)₂Et(NⁱPrH), Si(OEt)Et(NⁱPrH)₂, Si(OPr)Met₂(NⁱPrH), Si(OPr)₂Met(NⁱPrH), Si(OPr)₃(NⁱPrH), Si(OPr)₂H(NⁱPrH), Si(OPr)H₂(NⁱPrH), Si(OPr)Met(NⁱPrH)₂, Si(OPr)H(NⁱPrH)₂, Si(OPr)₂(NⁱPrH)₂, Si(OPr)(NⁱPrH)₃, Si(OPr)Et₂(NⁱPrH), Si(OPr)₂Et(NⁱPrH), Si(OPr)Et(NⁱPrH)₂, Si(OPr)Pr₂(NⁱPrH), Si(OPr)₂Pr(NⁱPrH), Si(OPr)Pr(NⁱPrH)₂, Si(OⁱPr)Met₂(NⁱPrH), Si(OⁱPr)₂Met(NⁱPrH), Si(OⁱPr)₃(NⁱPrH), Si(OⁱPr)₂H(NⁱPrH), Si(OⁱPr)H₂(NⁱPrH), Si(OⁱPr)Met(NⁱPrH)₂, Si(OⁱPr)H(NⁱPrH)₂, Si(OⁱPr)₂(NⁱPrH)₂, Si(OⁱPr)(NⁱPrH)₃, Si(OⁱPr)Et₂(NⁱPrH), Si(OⁱPr)₂Et(NⁱPrH), Si(OⁱPr)Et(NⁱPrH)₂, Si(OⁱPr)ⁱPr₂(NⁱPrH), Si(OⁱPr)₂iPr(NⁱPrH), Si(OⁱPr)ⁱPr(NⁱPrH)₂, Si(OⁱPr)Pr₂(NⁱPrH), Si(OⁱPr)₂Pr(NⁱPrH) and Si(OⁱPr)Pr(NⁱPrH)₂.

In some embodiments, the second atom is a nitrogen of a dialkylamine group, i.e. a nitrogen atom of a tertiary amine. In some embodiments, the inhibitor reactant is selected from a group consisting of Si(OMet)Met₂(NMet₂), Si(OMet)₂Met(NMet₂), Si(OMet)₃(NMet₂), Si(OMet)₂H(NMet₂), Si(OMet)H₂(NMet₂), Si(OMet)Met(NMet₂)₂, Si(OMet)H(NMet₂)₂, Si(OMet)₂(NMet₂)₂, Si(OMet)(NMet₂)₃, Si(OEt)Met₂(NMet₂), Si(OEt)₂Met(NMet₂), Si(OEt)₃(NMet₂), Si(OEt)₂H(NMet₂), Si(OEt)H₂(NMet₂), Si(OEt)Met(NMet₂)₂, Si(OEt)H(NMet₂)₂, Si(OEt)₂(NMet₂)₂, Si(OEt)(NMet₂)₃, Si(OMet)Et₂(NMet₂), Si(OMet)₂Et(NMet₂), Si(OMet)Et(NMet₂)₂, Si(OEt)Et₂(NMet₂), Si(OEt)₂Et(NMet₂), Si(OEt)Et(NMet₂)₂, Si(OPr)Met₂(NMet₂), Si(OPr)₂Met(NMet₂), Si(OPr)₃(NMet₂), Si(OPr)₂H(NMet₂), Si(OPr)H₂(NMet₂), Si(OPr)Met(NMet₂)₂, Si(OPr)H(NMet₂)₂, Si(OPr)₂(NMet₂)₂, Si(OPr)(NMet₂)₃, Si(OPr)Et₂(NMet₂), Si(OPr)₂Et(NMet₂), Si(OPr)Et(NMet₂)₂, Si(OPr)Pr₂(NMet₂), Si(OPr)₂Pr(NMet₂), Si(OPr)Pr(NMet₂)₂, Si(OⁱPr)Met₂(NMet₂), Si(OⁱPr)₂Met(NMet₂), Si(OⁱPr)₃(NMet₂), Si(OⁱPr)₂H(NMet₂), Si(OⁱPr)H₂(NMet₂), Si(OⁱPr)Met(NMet₂)₂, Si(OⁱPr)H(NMet₂)₂, Si(OⁱPr)₂(NMet₂)₂, Si(OⁱPr)(NMet₂)₃, Si(OⁱPr)Et₂(NMet₂), Si(OⁱPr)₂Et(NMet₂), Si(OⁱPr)Et(NMet₂)₂, Si(OⁱPr)ⁱPr₂(NMet₂), Si(OⁱPr)₂′Pr(NMet₂), Si(OⁱPr)ⁱPr(NMet₂)₂, Si(OⁱPr)Pr₂(NMet₂), Si(OⁱPr)₂Pr(NMet₂), Si(OⁱPr)Pr(NMet₂)₂, Si(OMet)Met₂(NEt₂), Si(OMet)₂Met(NEt₂), Si(OMet)₃(NEt₂), Si(OMet)₂H(NEt₂), Si(OMet)H₂(NEt₂), Si(OMet)Met(NEt₂)₂, Si(OMet)H(NEt₂)₂, Si(OMet)₂(NEt₂)₂, Si(OMet)(NEt₂)₃, Si(OEt)Met₂(NEt₂), Si(OEt)₂Met(NEt₂), Si(OEt)₃(NEt₂), Si(OEt)₂H(NEt₂), Si(OEt)H₂(NEt₂), Si(OEt)Met(NEt₂)₂, Si(OEt)H(NEt₂)₂, Si(OEt)₂(NEt₂)₂, Si(OEt)(NEt₂)₃, Si(OMet)Et₂(NEt₂), Si(OMet)₂Et(NEt₂), Si(OMet)Et(NEt₂)₂, Si(OEt)Et₂(NEt₂), Si(OEt)₂Et(NEt₂), Si(OEt)Et(NEt₂)₂, Si(OPr)Met₂(NEt₂), Si(OPr)₂Met(NEt₂), Si(OPr)₃(NEt₂), Si(OPr)₂H(NEt₂), Si(OPr)H₂(NEt₂), Si(OPr)Met(NEt₂)₂, Si(OPr)H(NEt₂)₂, Si(OPr)₂(NEt₂)₂, Si(OPr)(NEt₂)₃, Si(OPr)Et₂(NEt₂), Si(OPr)₂Et(NEt₂), Si(OPr)Et(NEt₂)₂, Si(OPr)Pr₂(NEt₂), Si(OPr)₂Pr(NEt₂), Si(OPr)Pr(NEt₂)₂, Si(OⁱPr)Met₂(NEt₂), Si(OⁱPr)₂Met(NEt₂), Si(OⁱPr)₃(NEt₂), Si(OⁱPr)₂H(NEt₂), Si(OⁱPr)H₂(NEt₂), Si(OⁱPr)Met(NEt₂)₂, Si(OⁱPr)H(NEt₂)₂, Si(OⁱPr)₂(NEt₂)₂, Si(OⁱPr)(NEt₂)₃, Si(OⁱPr)Et₂(NEt₂), Si(OⁱPr)₂Et(NEt₂), Si(OⁱPr)Et(NEt₂)₂, Si(OⁱPr)ⁱPr₂(NEt₂), Si(OⁱPr)₂ⁱPr(NEt₂), Si(OⁱPr)ⁱPr(NEt₂)₂, Si(OⁱPr)Pr₂(NEt₂), Si(OⁱPr)₂Pr(NEt₂), Si(OⁱPr)Pr(NEt₂)₂, Si(OMet)Met₂(NPr₂), Si(OMet)₂Met(NPr₂), Si(OMet)₃(NPr₂), Si(OMet)₂H(NPr₂), Si(OMet)H₂(NPr₂), Si(OMet)Met(NPr₂)₂, Si(OMet)H(NPr₂)₂, Si(OMet)₂(NPr₂)₂, Si(OMet)(NPr₂)₃, Si(OEt)Met₂(NPr₂), Si(OEt)₂Met(NPr₂), Si(OEt)₃(NPr₂), Si(OEt)₂H(NPr₂), Si(OEt)H₂(NPr₂), Si(OEt)Met(NPr₂)₂, Si(OEt)H(NPr₂)₂, Si(OEt)₂(NPr₂)₂, Si(OEt)(NPr₂)₃, Si(OMet)Et₂(NPr₂), Si(OMet)₂Et(NPr₂), Si(OMet)Et(NPr₂)₂, Si(OEt)Et₂(NPr₂), Si(OEt)₂Et(NPr₂), Si(OEt)Et(NPr₂)₂, Si(OPr)Met₂(NPr₂), Si(OPr)₂Met(NPr₂), Si(OPr)₃(NPr₂), Si(OPr)₂H(NPr₂), Si(OPr)H₂(NPr₂), Si(OPr)Met(NPr₂)₂, Si(OPr)H(NPr₂)₂, Si(OPr)₂(NPr₂)₂, Si(OPr)(NPr₂)₃, Si(OPr)Et₂(NPr₂), Si(OPr)₂Et(NPr₂), Si(OPr)Et(NPr₂)₂, Si(OPr)Pr₂(NPr₂), Si(OPr)₂Pr(NPr₂), Si(OPr)Pr(NPr₂)₂, Si(OⁱPr)Met₂(NPr₂), Si(OⁱPr)₂Met(NPr₂), Si(OⁱPr)₃(NPr₂), Si(OⁱPr)₂H(NPr₂), Si(OⁱPr)H₂(NPr₂), Si(OⁱPr)Met(NPr₂)₂, Si(OⁱPr)H(NPr₂)₂, Si(OⁱPr)₂(NPr₂)₂, Si(OⁱPr)(NPr₂)₃, Si(OⁱPr)Et₂(NPr₂), Si(OⁱPr)₂Et(NPr₂), Si(OⁱPr)Et(NPr₂)₂, Si(OⁱPr)ⁱPr₂(NPr₂), Si(OⁱPr)₂′Pr(NPr₂), Si(OⁱPr)ⁱPr(NPr₂)₂, Si(OⁱPr)Pr₂(NPr₂), Si(OⁱPr)₂Pr(NPr₂), Si(OⁱPr)Pr(NPr₂)₂, Si(OMet)Met₂(NⁱPr₂), Si(OMet)₂Met(NⁱPr₂), Si(OMet)₃(NⁱPr₂), Si(OMet)₂H(NⁱPr₂), Si(OMet)H₂(NⁱPr₂), Si(OMet)Met(NⁱPr₂)₂, Si(OMet)H(NⁱPr₂)₂, Si(OMet)₂(NⁱPr₂)₂, Si(OMet)(NⁱPr₂)₃, Si(OEt)Met₂(NⁱPr₂), Si(OEt)₂Met(NⁱPr₂), Si(OEt)₃(NⁱPr₂), Si(OEt)₂H(NⁱPr₂), Si(OEt)H₂(NⁱPr₂), Si(OEt)Met(NⁱPr₂)₂, Si(OEt)H(NⁱPr₂)₂, Si(OEt)₂(NⁱPr₂)₂, Si(OEt)(NⁱPr₂)₃, Si(OMet)Et₂(NⁱPr₂), Si(OMet)₂Et(NⁱPr₂), Si(OMet)Et(NⁱPr₂)₂, Si(OEt)Et₂(NⁱPr₂), Si(OEt)₂Et(NⁱPr₂), Si(OEt)Et(NⁱPr₂)₂, Si(OPr)Met₂(NⁱPr₂), Si(OPr)₂Met(NⁱPr₂), Si(OPr)₃(NⁱPr₂), Si(OPr)₂H(NⁱPr₂), Si(OPr)H₂(NⁱPr₂), Si(OPr)Met(NⁱPr₂)₂, Si(OPr)H(NⁱPr₂)₂, Si(OPr)₂(NⁱPr₂)₂, Si(OPr)(NⁱPr₂)₃, Si(OPr)Et₂(NⁱPr₂), Si(OPr)₂Et(NⁱPr₂), Si(OPr)Et(NⁱPr₂)₂, Si(OPr)Pr₂(NⁱPr₂), Si(OPr)₂Pr(NⁱPr₂), Si(OPr)Pr(NⁱPr₂)₂, Si(OⁱPr)Met₂(NⁱPr₂), Si(OⁱPr)₂Met(NⁱPr₂), Si(OⁱPr)₃(NⁱPr₂), Si(OⁱPr)₂H(NⁱPr₂), Si(OⁱPr)H₂(NⁱPr₂), Si(OⁱPr)Met(NⁱPr₂)₂, Si(OⁱPr)H(NⁱPr₂)₂, Si(OⁱPr)₂(NⁱPr₂)₂, Si(OⁱPr)(NⁱPr₂)₃, Si(OⁱPr)Et₂(NⁱPr₂), Sⁱ(OⁱPr)₂Et(NⁱPr₂), Si(OⁱPr)Et(NⁱPr₂)₂, Si(OⁱPr)ⁱPr₂(NⁱPr₂), Si(OⁱPr)₂iPr(NⁱPr₂), Si(OⁱPr)ⁱPr(NⁱPr₂)₂, Si(OⁱPr)Pr₂(NⁱPr₂), Si(OⁱPr)₂Pr(NⁱPr₂) and Si(OⁱPr)Pr(NⁱPr₂)₂.

Generally, the above inhibitor reactants having a nitrogen as the second atom may be described as listed below, using R to designate H, Met, Et, Pr, ⁱPr, Bu, sBu or tBu. Each R can be independently selected, so they can be same or different. Si(OMet)Met₂(NR₂), Si(OMet)₂Met(NR₂), Si(OMet)₃(NR₂), Si(OMet)₂H(NR₂), Si(OMet)H₂(NR₂), Si(OMet)Met(NR₂)₂, Si(OMet)H(NR₂)₂, Si(OMet)₂(NR₂)₂, Si(OMet)(NR₂)₃, Si(OEt)Met₂(NR₂), Si(OEt)₂Met(NR₂), Si(OEt)₃(NR₂), Si(OEt)₂H(NR₂), Si(OEt)H₂(NR₂), Si(OEt)Met(NR₂)₂, Si(OEt)H(NR₂)₂, Si(OEt)₂(NR₂)₂, Si(OEt)(NR₂)₃, Si(OMet)Et₂(NR₂), Si(OMet)₂Et(NR₂), Si(OMet)Et(NR₂)₂, Si(OEt)Et₂(NR₂), Si(OEt)₂Et(NR₂), Si(OEt)Et(NR₂)₂, Si(OPr)Met₂(NR₂), Si(OPr)₂Met(NR₂), Si(OPr)₃(NR₂), Si(OPr)₂H(NR₂), Si(OPr)H₂(NR₂), Si(OPr)Met(NR₂)₂, Si(OPr)H(NR₂)₂, Si(OPr)₂(NR₂)₂, Si(OPr)(NR₂)₃, Si(OPr)Et₂(NR₂), Si(OPr)₂Et(NR₂), Si(OPr)Et(NR₂)₂, Si(OPr)Pr₂(NR₂), Si(OPr)₂Pr(NR₂), Si(OPr)Pr(NR₂)₂, Si(OⁱPr)Met₂(NR₂), Si(OⁱPr)₂Met(NR₂), Si(OⁱPr)₃(NR₂), Si(OⁱPr)₂H(NR₂), Si(OⁱPr)H₂(NR₂), Si(OⁱPr)Met(NR₂)₂, Si(OⁱPr)H(NR₂)₂, Si(OⁱPr)₂(NR₂)₂, Si(OⁱPr)(NR₂)₃, Si(OⁱPr)Et₂(NR₂), Si(OⁱPr)₂Et(NR₂), Si(OⁱPr)Et(NR₂)₂, Si(OⁱPr)ⁱPr₂(NR₂), Si(OⁱPr)₂′Pr(NR₂), Si(OⁱPr)ⁱPr(NR₂)₂, Si(OⁱPr)Pr₂(NR₂), Si(OⁱPr)₂Pr(NR₂), Si(OⁱPr)Pr(NR₂)₂, Si(OMet)Met₂(NRH), Si(OMet)₂Met(NRH), Si(OMet)₃(NRH), Si(OMet)₂H(NRH), Si(OMet)H₂(NRH), Si(OMet)Met(NRH)₂, Si(OMet)H(NRH)₂, Si(OMet)₂(NRH)₂, Si(OMet)(NRH)₃, Si(OEt)Met₂(NRH), Si(OEt)₂Met(NRH), Si(OEt)₃(NRH), Si(OEt)₂H(NRH), Si(OEt)H₂(NRH), Si(OEt)Met(NRH)₂, Si(OEt)H(NRH)₂, Si(OEt)₂(NRH)₂, Si(OEt)(NRH)₃, Si(OMet)Et₂(NRH), Si(OMet)₂Et(NRH), Si(OMet)Et(NRH)₂, Si(OEt)Et₂(NRH), Si(OEt)₂Et(NRH), Si(OEt)Et(NRH)₂, Si(OPr)Met₂(NRH), Si(OPr)₂Met(NRH), Si(OPr)₃(NRH), Si(OPr)₂H(NRH), Si(OPr)H₂(NRH), Si(OPr)Met(NRH)₂, Si(OPr)H(NRH)₂, Si(OPr)₂(NRH)₂, Si(OPr)(NRH)₃, Si(OPr)Et₂(NRH), Si(OPr)₂Et(NRH), Si(OPr)Et(NRH)₂, Si(OPr)Pr₂(NRH), Si(OPr)₂Pr(NRH), Si(OPr)Pr(NRH)₂, Si(OⁱPr)Met₂(NRH), Si(OⁱPr)₂Met(NRH), Si(OⁱPr)₃(NRH), Si(OⁱPr)₂H(NRH), Si(OⁱPr)H₂(NRH), Si(OⁱPr)Met(NRH)₂, Si(OⁱPr)H(NRH)₂, Si(OⁱPr)₂(NRH)₂, Si(OⁱPr)(NRH)₃, Si(OⁱPr)Et₂(NRH), Si(OⁱPr)₂Et(NRH), Si(OⁱPr)Et(NRH)₂, Si(OⁱPr)ⁱPr₂(NRH), Si(OⁱPr)₂ⁱPr(NRH), Si(OⁱPr)ⁱPr(NRH)₂, Si(OⁱPr)Pr₂(NRH), Si(OⁱPr)₂Pr(NRH) and Si(OⁱPr)Pr(NRH)₂.

In some embodiments, the inhibitor reactant is selected from a group consisting of Si(OMet)₃Cl, Si(OMet)₃Br, Si(OMet)₃I, Si(OMet)₂Cl₂, Si(OMet)₂Br₂, Si(OMet)₂I₂, Si(OEt)₃Cl, Si(OEt)₃Br, Si(OEt)₃I, Si(OEt)₂Cl₂, Si(OEt)₂Br₂, Si(OEt)₂I₂, Si(OMet)₃(NH₂), Si(OMet)₂(NH₂)₂, Si(OEt)₃(NH₂), Si(OEt)₂(NH₂)₂, Si(OMet)₃(NMet₂), Si(OMet)₂(NMet₂)₂, Si(OEt)₃(NMet₂), Si(OEt)₂(NMet₂)₂, Si(OMet)₃(NMetH), Si(OMet)₂(NMetH)₂, Si(OEt)₃(NMetH), Si(OEt)₂(NMetH)₂, Si(OMet)₃(NEt₂), Si(OMet)₂(NEt₂)₂, Si(OEt)₃(NEt₂) and Si(OEt)₂(NEt₂)₂.

In the methods according to the current disclosure, the inhibitor reactant selectively forms inhibitor material on the first surface. Without limiting the current disclosure to any specific theory, the inhibitor reactant may have higher affinity to dielectric or non-conductive surfaces, particularly silicon oxide-comprising surfaces, through a specific component. As a result, the dielectric surface may become silylated, which, possibly together with additional treatments of the substrate, may prevent further deposition on the first surface. For example, deposition of an organic polymer on the first surface may be reduced or substantially prevented by the inhibitor material. An organic polymer, such as a polyimide-comprising organic polymer may be used as an intermediate passivation of the second surface, and the deposition of a target material on the first surface may be achieved on the first surface after depositing the organic polymer on the second surface. The inhibitor material may be removed before depositing the target material, but it may not be necessary. In some embodiments, the inhibitor material is partially removed from the first surface before depositing the target material on the first surface.

In accordance with some exemplary embodiments, a structure is formed using methods as described herein. Exemplary structures can further include one or more layers, such as metal, metallic or conducting layers overlying the dielectric or other layers deposited using the methods of selectively depositing inhibitor material and/or an organic polymer. The structure can be or form part of a CMOS structure, such as one or more of a PMOS and NMOS structure, or other device structure.

In accordance with yet additional embodiments of the disclosure, a device or portion thereof can be formed using methods and/or structures as described herein. The device can be or form part of, for example, a CMOS device.

The current disclosure also relates to methods of depositing silicon-containing material on a substrate is disclosed. The silicon-containing material may be inhibitor material, and the silicon reactant used to deposit the silicon-containing material may be the same compound as inhibitor reactant as disclosed herein. However, a silicon reactant may be used differently from an inhibitor reactant, as its purpose is not to inhibit the deposition of another material, but the silicon-containing material may serve a function in the final semiconductor device produced by methods disclosed herein. The methods of depositing silicon-containing material comprises providing the substrate in a reaction chamber, and contacting the substrate with a vapor-phase silicon reactant having a formula Si(OR)ₐX_{b}R′_{c}. In the formula, each R is independently selected from linear, branched and cyclic C1 to C6 alkyls and phenyl, each R′ is independently selected from H, linear, branched and cyclic C1 to C6 alkyls and phenyl, X is selected from NR′₂, a is 1, 2 or 3; b is 1 or 2; c is 0, 1 or 2; and a+b+c=4. The silicon reactant forms silicon-containing material on the surface. In some embodiments, the silicon-containing material is an inhibitor. An inhibitor according to the current disclosure means a substance on a surface of a substrate reducing or inhibiting the deposition of a target material. In some embodiments, the silicon-containing material has a silicon to oxygen ratio from about 1:1 to 1:3. In some embodiments, the silicon-containing material is not subjected to oxidation. In some embodiments, the silicon-containing material is not contacted with an oxygen precursor.

In one aspect, a method of selectively depositing a metal-containing material on a dielectric surface of a substrate relative to a metal-containing surface of the same substrate is disclosed. The metal-containing surface may be an elemental metal surface, such as a copper surface, a cobalt surface, a molybdenum surface or a tungsten surface or a combination thereof.

In some embodiments, the dielectric surface comprises or consists substantially of silicon oxide. In some embodiments, the dielectric surface forms at least a part of a sidewall of a feature and the metal-containing surface forms at least a part of a bottom of the feature. In some embodiments, the deposited metal-containing material is a metal nitride. In some embodiments, the deposited metal-containing material is a metal oxide. In some embodiments, the deposited metal-containing material is selected from yttrium oxide, aluminum oxide, titanium nitride and tantalum nitride. In some embodiments, the deposited metal-containing material is an elemental metal. In some embodiments, the metal-containing surface comprises a polyimide-comprising passivation, and the dielectric surface comprises inhibitor material according to the current disclosure.

In a yet further aspect, a vapor deposition vessel comprising an inhibitor reactant having a formula Si(OR)ₐX_{b}R′_{c}, is disclosed. In the formula, each R is independently selected from linear, branched and cyclic C1 to C6 alkyls and phenyl, each R′ is independently selected from H, linear, branched and cyclic C1 to C6 alkyls and phenyl, X is selected from NR′₂, a is 1, 2 or 3; b is 1 or 2; c is 0, 1 or 2; and a+b+c=4. The vapor deposition vessel according to the current disclosure is configured and arranged for vapor deposition. It may contain features, such as valves, outlets, a shell or other structural features necessary for being used in a vapor deposition assembly.

### DRAWINGS

The disclosure is further explained by the following exemplary embodiments depicted in the drawings. The illustrations presented herein are not meant to be actual views of any particular material, structure, or assembly, but are merely schematic representations to describe embodiments of the current disclosure. It will be appreciated that elements in the figures are illustrated for simplicity and clarity and have not necessarily been drawn to scale. For example, the dimensions of some of the elements in the figures may be exaggerated relative to other elements to help improve the understanding of illustrated embodiments of the present disclosure. Specifically, relative etch rates of different materials indicated in the drawings may deviate from the experimental results, the specifics of which may vary according to process conditions. The layers, structures, devices and processing assemblies depicted in the drawings may contain additional elements and details, which may be omitted for clarity.

For the sake of brevity, conventional manufacturing, connection, preparation, and other functional aspects of the methods, layers, structures, devices and processing assemblies described herein may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

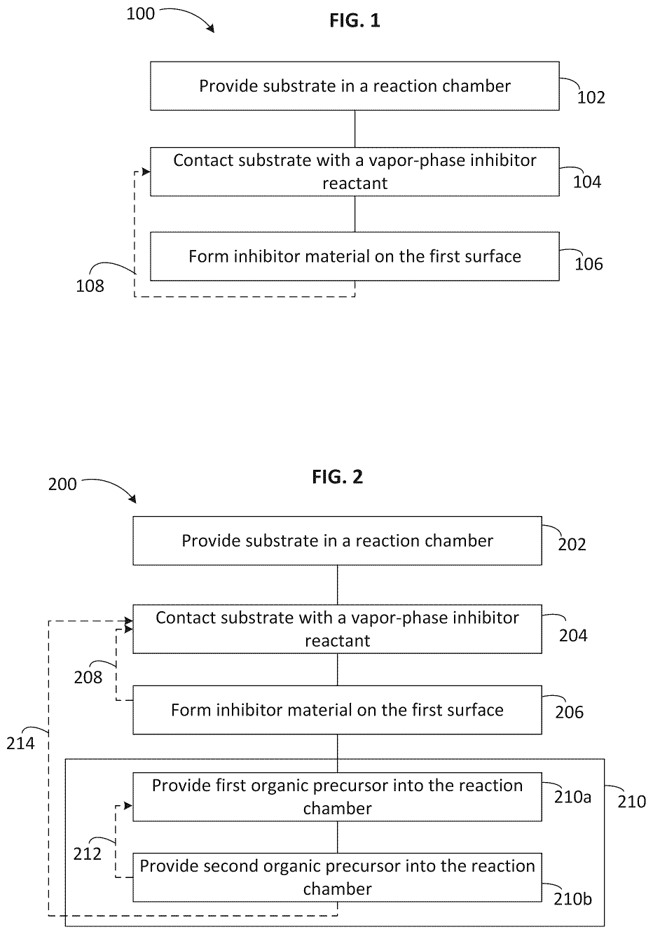

FIG. 1 is a block diagram of an exemplary embodiment of a method 100 according to the current disclosure. First, a substrate is provided in a reaction chamber at stage 102. The substrate comprises a first surface and a second surface as described in the current disclosure. For example, the first surface may be a dielectric surface, and the second surface may be metal or a metallic surface. In some embodiments, the first surface is a silicon-containing dielectric surface, such as a silicon oxide surface or a low k surface, e.g. SiOC surface. The first surface and the second surface may be adjacent surfaces. They can be positioned on the same vertical plane and have the same orientation. However, the first surface and the second surface may alternatively be two surfaces of a feature, such as a gap, via, fin or the like. In some embodiments, the first surface is a sidewall of a feature. In some embodiments, the first surface is an outside sidewall of a feature. In some embodiments, the first surface is an inside sidewall of a feature. In some embodiments, the second surface is a bottom of a feature. In some embodiments, the second surface is a top surface of a feature. In some embodiments, the feature comprises a first metal surface at the bottom of the feature. The bottom may be substantially coplanar with the substrate surface. In some embodiments, the feature comprises a second dielectric, such as a silicon oxide, surface substantially perpendicular to the bottom of the feature.

In some embodiments, the first surface comprises material selected from a group consisting of SiO₂, SiN, SiC, SiOC, SiON, SiOCN, SiGe and combinations thereof. In some embodiments, the first surface is a dielectric surface. In some embodiments, the first surface is a low-k surface. By a low k surface is herein meant a surface having at most a similar k value as silicon oxide. In some embodiments, the first surface comprises an oxide. In some embodiments, the first surface comprises a nitride. In some embodiments, the first surface comprises silicon. In some embodiments, the first surface comprises silicon-based dielectric material. Examples of silicon-comprising dielectric materials include silicon oxide-based materials, including grown or deposited silicon dioxide, doped and/or porous oxides and native oxide on silicon. In some embodiments, the first surface comprises silicon oxide. In some embodiments, the first surface is a silicon oxide surface, such as a native oxide surface, a thermal oxide surface or a chemical oxide surface. In some embodiments, the first surface comprises carbon. In some embodiments, the first surface comprises SiN. In some embodiments, the first surface comprises SiOC. In some embodiments, the first surface is an etch-stop layer. An etch-stop layer may comprise, for example a nitride.

In some embodiments, the second surface is an electrically conductive surface. In some embodiments, the second surface comprises a material selected from a group consisting of a metal, amorphous carbon, metal oxide and metal nitride. In some embodiments, the second surface comprises a transition metal. In some embodiments, the second surface comprises elemental metal. In some embodiments, the second surface is elemental metal.

In some embodiments, the second surface comprises elemental molybdenum. In some embodiments, the second surface is elemental molybdenum. In some embodiments, the second surface comprises elemental tungsten. In some embodiments, the second surface is elemental tungsten. In some embodiments, the second surface comprises elemental cobalt. In some embodiments, the second surface is elemental cobalt. In some embodiments, the second surface comprises elemental copper. In some embodiments, the second surface is elemental copper. In some embodiments, the second surface comprises titanium nitride. In some embodiments, the second surface is titanium nitride. In some embodiments, the second surface comprises tantalum nitride. In some embodiments, the second surface is tantalum nitride. In some embodiments, the second surface comprises aluminum nitride. In some embodiments, the second surface is aluminum nitride.

For embodiments in which one surface of the substrate comprises a metal, the surface is referred to as a metal surface. In some embodiments, a metal surface consists essentially of, or consists of one or more metals. A metal surface may be a metal surface or a metallic surface. In some embodiments the metal or metallic surface may comprise metal, metal oxides, and/or mixtures thereof. In some embodiments the metal or metallic surface may comprise surface oxidation. In some embodiments the metal or metallic material of the metal or metallic surface is electrically conductive with or without surface oxidation. In some embodiments, metal or a metallic surface comprises one or more transition metals. In some embodiments, the metal or metallic surface comprises one or more transition metals from groups 4 to 11 of the periodic table of elements.

In some embodiments, the second surface comprises a metal selected from a group consisting of Ti, V, Nb, Ta, Cr, Mo, W, Mn, Fe, Co, Ni, Cu, Zn, Ru and Al. Thus, in some embodiments, the second surface comprises titanium. In some embodiments, the second surface comprises vanadium. In some embodiments, the second surface comprises niobium. In some embodiments, the second surface comprises tantalum. In some embodiments, the second surface comprises chromium. In some embodiments, the second surface comprises molybdenum. In some embodiments, the second surface comprises tungsten. In some embodiments, the second surface comprises manganese. In some embodiments, the second surface comprises iron. In some embodiments, the second surface comprises cobalt. In some embodiments, the second surface comprises nickel. In some embodiments, the second surface comprises copper. In some embodiments, the second surface comprises zinc. In some embodiments, the second surface comprises ruthenium. In some embodiments, the second surface comprises aluminum.

In some embodiments, the second surface comprises elemental titanium. In some embodiments, the second surface comprises elemental vanadium. In some embodiments, the second surface comprises elemental niobium. In some embodiments, the second surface comprises elemental tantalum. In some embodiments, the second surface comprises elemental chromium. In some embodiments, the second surface comprises elemental molybdenum. In some embodiments, the second surface comprises elemental tungsten. In some embodiments, the second surface comprises elemental manganese. In some embodiments, the second surface comprises elemental iron. In some embodiments, the second surface comprises elemental cobalt. In some embodiments, the second surface comprises elemental nickel. In some embodiments, the second surface comprises elemental copper. In some embodiments, the second surface comprises elemental zinc. In some embodiments, the second surface comprises elemental ruthenium. In some embodiments, the second surface comprises elemental aluminum. In some embodiments, the second surface comprises an alloy of two or more metals.

In some embodiments, a metallic surface comprises titanium nitride. In some embodiments, the metal or metallic surface comprises one or more noble metals, such as Ru. In some embodiments, the metal or metallic surface comprises a conductive metal oxide. In some embodiments, the metal or metallic surface comprises a conductive metal nitride. In some embodiments, the metal or metallic surface comprises a conductive metal carbide. In some embodiments, the metal or metallic surface comprises a conductive metal boride. In some embodiments, the metal or metallic surface comprises a combination conductive materials. For example, the metal or metallic surface may comprise one or more of ruthenium oxide (RuOx), niobium carbide (NbCx), niobium boride (NbBx), nickel oxide (NiOx), cobalt oxide (CoOx), niobium oxide (NbOx), tungsten carbonitride (WNCx), tantalum nitride (TaN), or titanium nitride (TiN).

In some embodiments, the substrate comprises a first dielectric surface and a second metal or metallic surface. In some embodiments, the substrate comprises a second metal nitride surface. In some embodiments, the substrate comprises a second electrically conductive metal nitride surface. In some embodiments, the second surface may comprise H terminations. In some embodiments, the first surface may be a SiO₂-based surface. In some embodiments, the first surface may comprise Si—O bonds. In some embodiments, the first surface may comprise a SiO₂-based low-k material. In some embodiments, the first surface may comprise more than about 30%, or more than about 50% of SiO₂. In certain embodiments the first surface may comprise or consist of a silicon dioxide surface.

In some embodiments, the first surface is a SiO₂ surface and the second surface is a metal surface. In some embodiments, the first surface is a SiN surface, and the second surface is a metal surface, such as an elemental metal surface. In some embodiments, the first surface is a SiOC surface and the second surface is a metal surface. In some embodiments, the first surface is a SiON surface and the second surface is a metal surface. In some embodiments, the first surface is a SiOCN surface and the second surface is a metal surface. The second metal surface may be, for example, a copper surface, a ruthenium surface, a tungsten surface, a cobalt surface or a molybdenum surface. In some embodiments the second surface comprises a metal oxide. In some embodiments, the second surface comprises aluminum oxide. In some embodiments, a metal oxide surface is an oxidized surface of a metallic material. In some embodiments, a metal oxide surface is created by oxidizing at least the surface of a metallic material using oxygen compound, such as compounds comprising O₃, H₂O, H₂O₂, O₂, oxygen atoms, plasma or radicals or mixtures thereof. In some embodiments, a metal oxide surface is a native oxide formed on a metallic material.

In some embodiments, a metal oxide layer, is selectively deposited on a first dielectric surface of a substrate relative to a second conductive (e.g., metal or metallic) surface of the substrate. In some embodiments, the first surface comprises hydroxyl (—OH) groups. In some embodiments, the second surface comprises hydrogen (—H) terminations.

In some embodiments, inhibitor material, such as an inhibitor layer, is selectively deposited on a first silicon-containing surface relative to a second metal oxide surface of a substrate. In some embodiments, the metal oxide is selected from aluminum oxide, hafnium oxide and zirconium oxide. In some embodiments, the second surface comprises a high k material. In some embodiments, the high k material is selected from a group consisting of hafnium oxide, zirconium oxide and combinations thereof. In some embodiments, the second surface is a hafnium oxide surface. In some embodiments, the second surface is a zirconium oxide surface. In some embodiments, the second surface is a hafnium zirconium oxide surface. In some embodiments, the second surface is hafnium oxide surface and the first surface is a silicon-containing surface, such as a silicon and oxygen-containing surface. In some embodiments, the second surface is zirconium oxide surface and the first surface is a silicon-containing surface. In some embodiments, the second surface is hafnium zirconium oxide surface and the first surface is a silicon-containing surface.

The substrate may be heated at stage 102 prior to providing a vapor-phase inhibitor reactant into the reaction chamber.

At stage 104, the substrate is contacted with a vapor-phase inhibitor reactant. In an exemplary embodiment, the inhibitor reactant may comprise a trialkoxydialkylaminosilane. Contacting the substrate with the inhibitor reactant may be performed at a temperature of below 400° C., such as at a temperature from about 100° C. to about 400° C., for example at a temperature of about 200° C. or at a temperature of about 250° C. or at a temperature of about 300° C. or at a temperature of about 320° C. or at a temperature of about 350° C.

At stage 106, inhibitor material is formed on the first surface. Forming the inhibitor material in 106 may not be a discrete step, but it may happen as the substrate is contacted with the vapor-phase inhibitor reactant. Depending on the deposition conditions, forming of the inhibitor material may take place substantially instantaneously as the inhibitor reactant comes into contact with the first surface of the substrate. In some embodiments, there may be a delay in the formation of the inhibitor material, or the inhibitor reactant on the substrate surface may be treated to induce the formation of the inhibitor material on the first surface.

Contacting the substrate with the inhibitor reactant is performed by providing the inhibitor reactant into the reaction chamber. Contacting of the substrate with the inhibitor reactant may be performed for a length sufficient to accumulate suitable amount of inhibitor material on the first surface of the substrate. For example, the inhibitor reactant may be contacted with the substrate for at least about 10 seconds, such as from about 10 seconds to about 400 seconds, for example, from about 30 seconds to about 300 seconds, or from about 30 seconds to about 240 seconds, or from about 30 seconds to about 200 seconds, or from about 60 seconds to about 300 seconds, or from about 100 seconds to about 300 seconds, or from about 100 seconds to about 200 seconds or from about 200 seconds to about 300 seconds. The length of the inhibitor treatment depends on the processing conditions, such as temperature, pressure, partial pressure of the inhibitor reactant and the reactivity of the inhibitor reactant towards the material of the first surface. The inhibitor reactant may be contacted with the substrate in separate pulses. The reaction chamber may be purged between pulses of the inhibitor reactant. For example, a pulse length from about 0.5 seconds to about 10 seconds may be used. In some tests, a pulse length of 5 seconds was used. In some embodiments, the inhibitor reactant was provided into the reaction chamber from about 15 to about 30, such as in about 20 or in about 25, cycles. The inhibitor reactant may be provided into the reaction chamber in pulses to contact the substrate, and the reaction chamber may optionally be purged between pulses (loop 108 in FIG. 1). The length of a purge between two consecutive pulses may vary between 0.5 seconds and 5 seconds, for example. Depositing of an organic polymer, may be performed before repeating contacting the substrate with the vapor-phase inhibitor reactant at 104. The frequency of depositing inhibitor material on the substrate may depend on if the inhibitor material is consumed or loses its inhibition properties during the deposition of an organic polymer. A suitable frequency of depositing inhibitor material may be determined experimentally.

In some embodiments, the substrate may be pretreated or cleaned prior to or at the beginning of the selective deposition process of inhibitor material. In some embodiments, the substrate may be subjected to a plasma cleaning process at prior to or at the beginning of the selective deposition process. In some embodiments, a plasma cleaning process may not include ion bombardment, or may include relatively small amounts of ion bombardment. For example, in some embodiments, the substrate surface may be exposed to plasma, radicals, excited species, and/or atomic species prior to or at the beginning of the selective deposition process. In some embodiments, the substrate surface may be exposed to hydrogen plasma, radicals, or atomic species prior to or at the beginning of the selective deposition process. In some embodiments, a pretreatment or cleaning process may be carried out in the same reaction chamber as a selective deposition process. However, in some embodiments, a pretreatment or cleaning process may be carried out in a separate reaction chamber.

FIG. 2 is a block diagram of another exemplary embodiment of a method according to the current disclosure. In the method 200 of FIG. 2, blocks 202, 204, 206 and 208 are performed as described for the corresponding blocks 102, 104, 106 and 108 in the embodiment of FIG. 1. In the embodiment of FIG. 2, the method comprises depositing organic polymer 210.

Loop 208 corresponds to loop 108 of FIG. 1 and indicates that the deposition of inhibition material may be repeated after initially passivating the first surface against deposition of organic polymer. However, the optional loop 214 indicates that the deposition of inhibitor material may be repeated during the selective deposition process of the organic polymer 210.

The deposition of an organic polymer according to the current disclosure 210 is performed by a cyclic vapor deposition process. For example, the deposition of the organic polymer may be an MLD process. The deposition of an organic polymer comprises providing a first vapor-phase organic precursor into the reaction chamber 210a and providing a second vapor-phase organic precursor into the reaction chamber 210b. Providing a first vapor-phase organic precursor 210a and providing a second vapor-phase organic precursor 210b may define a deposition cycle. The deposition cycle may be repeated (loop 212) until a suitable thickness of the organic polymer has been deposited on the second surface of the substrate. The first and second vapor-phase organic precursors form the organic polymer selectively on the second surface. In some embodiments, the organic polymer comprises polyimide. In some embodiments, the organic polymer comprises polyamide. In some embodiments, the organic polymer forms a passivation layer on the second surface.

Various reactants can be used to deposit organic polymer according to the processes 210 described herein. For example, in some embodiments, the first organic precursor is a diamine. In some embodiments, the first reactant can be, for example, 1,6-diaminohexane, 1,3-diaminopentane, triamine, such as tris(2-aminoethyl)amine, or a cyclic compound comprising at least two primary amine groups, such as 1,4-diaminocyclohexane or p-phenylenediamine. In some embodiments, the substrate is contacted with the first organic precursor before it is contacted with the second organic precursor. Thus, in some embodiments, the substrate may be contacted with a diamine before it is contacted with a second organic precursor. However, in some embodiments, the deposition

In some embodiments, the second organic precursor is capable of reacting with adsorbed species of the first reactant under the deposition conditions. For example, in some embodiments, the second organic precursor is an anhydride, such as furan-2,5-dione (maleic acid anhydride). The anhydride can be a dianhydride, e.g., pyromellitic dianhydride (PMDA). In some embodiments, the second reactant can be any other monomer with two reactive groups which will react with the first reactant.

In some embodiments, the organic precursors do not contain metal atoms. In some embodiments, the organic precursors do not contain semimetal atoms. In some embodiments, one of the organic precursors comprises metal or semimetal atoms. In some embodiments, the organic precursors contain carbon and hydrogen and one or more of the following elements: N, O, S, P or a halide, such as Cl or F.

In some embodiments, organic precursors for use in the selective deposition of an organic polymer 210 may be aliphatic compounds comprising 1-6 carbon atoms, 2-5 carbon atoms, 2-4 carbon atoms, 5 or fewer carbon atoms, 4 or fewer carbon atoms, 3 or fewer carbon atoms, or 2 carbon atoms. In some embodiments, the bonds between carbon atoms in the reactant or precursor may be single bonds, double bonds, triple bonds, or some combination thereof. Thus, in some embodiments, a first organic precursor may comprise two amino groups. In some embodiments, the amino groups of a first organic precursor may occupy one or both terminal positions on an aliphatic carbon chain. However, in some embodiments, the amino groups of a first organic precursor may not occupy either terminal position on an aliphatic carbon chain. In some embodiments, a first organic precursor may comprise a diamine. In some embodiments, a first organic precursor may comprise an organic precursor selected from the group of 1,2-diaminoethane, 1,3-diaminopropane, 1,4-diaminobutane, 1,5-diaminopentane, 1,2-diaminopropane, 2,3-butanediamine, 2,2-dimethyl-1,3-propanediamine.

In some embodiments, the first organic precursor provided into the reaction chamber at 210a is a liquid precursor under standard conditions. In some embodiments, the first organic precursor being vaporized comprises a diamine, such as 1,6-diaminohexane, 1,3-diaminopentane, triamine, such as tris(2-aminoethyl)amine, or a cyclic compound comprising at least two primary amine groups, such as 1,4-diaminocyclohexane or p-phenylenediamine. The substrate is then exposed to the first organic precursor vapor 210a. The substrate is also exposed to a second vapor-phase precursor 210b, for example an organic precursor, such as a dianhydride. A dianhydride may be, for example, pyromellitic dianhydride (PMDA). The cyclic exposure of the substrate to the first and second organic precursors leads to the deposition of an organic polymer. The method can include additional steps, and may be repeated, but need not be performed in the illustrated sequence nor the same sequence in each repetition, and it can be readily extended to more complex vapor deposition techniques.

The first organic precursor according to the current disclosure may comprise at least two carbon atoms, such as 1,2-diaminoethane. In some embodiments, first organic precursor comprises three carbon atoms. In some embodiments, first organic precursor comprises four carbon atoms. For example, first organic precursor may be selected from 1,2-diaminobutane, 1,3-diaminobutane, 1,4-diaminobutane and 2,4-diaminobutane. Thus, in some embodiments, at least one of the amino groups is attached to a carbon atom that is bonded to two other carbon atoms. In other words, at least one of the amino groups may be located at the end of a carbon chain. In some embodiments, a diamine according to the current comprises five carbon atoms. In some embodiments, a diamine according to the current comprises six carbon atoms.

In some embodiments, the carbon chain of the first organic precursor is branched. Thus, there is at least one carbon atom which is bonded to three or four other carbon atoms. In some embodiments, there is one such branching position in the first organic precursor. In some embodiments, there are two such branching positions in the first organic precursor. In some embodiments, there are three or more branching points. In some embodiments, the side chain from the longer carbon chain is a methyl group. In some embodiments, the side chain from the longer carbon chain is an ethyl group. In some embodiments, the side chain from the longer carbon chain is a propyl group. In some embodiments, the side chain from the longer carbon chain is an isopropyl group. In some embodiments, the side chain from the longer carbon chain is a butyl group. In some embodiments, the side chain from the longer carbon chain is a tert-butyl group. In some embodiments, a side chain of a first organic precursor is a straight alkyl chain. In some embodiments, a side chain of a first organic precursor is a branched alkyl chain. In some embodiments, a side chain of a first organic precursor is a cyclic alkyl chain.

In some embodiments, the first organic precursor is a C2 to C1I compound. The number of carbon atoms in the first organic precursor typically influences the volatility of the compound such that a higher-weight compound may not be as volatile as a smaller compound. However, it was found out that intermediate-sized first organic precursors containing, for example, four, five or six carbon atoms, may have suitable properties for being used as a first organic precursor in the selective deposition processes according to the current disclosure. For example, 1,3-diaminopentane is liquid at room temperature, has a boiling point of 164° C. under atmospheric pressure, a vapor pressure of about 2.22 Torr at 25° C. and reaches a vapor pressure of 1 Torr at temperatures below 20° C. Thus, when 1,3-diaminopentane is used as a precursor for organic polymer deposition according to the current disclosure, the precursor vessel does not need to be heated. This may be advantageous for the on-tool lifetime of the precursor, as it may be less prone to degradation during continued use. Further, a liquid precursor has an advantage that precursor vessel loading is less expensive than for solid precursors. In some embodiments, the first organic precursor comprises 1,3-diaminopentane.

In some embodiments of the disclosure, the amine groups are attached to non-adjacent carbon atoms. This may have advantages for the availability for the amine groups to reactions with the second precursor. In some embodiments, there is one carbon atom between the amino group-binding carbon atoms. In some embodiments, there is at least one carbon atom between the amino group-binding carbon atoms. In some embodiments, there are two carbon atoms between the amino group-binding carbon atoms. In some embodiments, there are at least two carbon atoms between the amino group-binding carbon atoms. In some embodiments, there are three carbon atoms between the amino group-binding carbon atoms. In some embodiments, there are at least three carbon atoms between the amino group-binding carbon atoms. In some embodiments, there are four carbon atoms between the amino group-binding carbon atoms. In some embodiments, there are at least four carbon atoms between the amino group-binding carbon atoms.

In some embodiments, the first organic precursor comprises 1,5-diamino-2-methylpentane. Although the vapor pressure of 1,5-diamino-2-methylpentane is lower than that of 1,3-diaminopentane, it is also liquid at ambient temperature, and reaching vapor pressure of 1 Torr requires a moderate temperature of about 40° C.

In some embodiments, a carbon atom bonded with an amine nitrogen in the first organic precursor is bonded to at least two carbon atoms. Thus, in some embodiments in which the first organic precursor comprises five or more carbons, at least one of the amino groups may be located away from the end of a carbon chain. The structure of the first organic precursor affects its properties in a vapor deposition process. Branching of a first organic precursor, including the number of branches, and the relative position of the amino groups to the branches, may cause the deposited organic polymer to have different properties. Without limiting the current disclosure to any specific theory, for example steric factors, may lead to certain reactions being preferred in This may offer the possibility to design a deposition process for a given purpose, taking into account for example the thermal budget, organic polymer growth speed requirements, necessary degree of selectivity, by using different first organic precursors.

In some embodiments, the first organic precursor is a cyclic diamine. In some embodiments, the first organic precursor comprises a cyclopentanedialkylamine, cyclohexanedialkylamine, cyclopentadienedialkylamine, benzenedialkylamine, cyclopentanetrialkylamine, cyclohexanetrialkylamine, cyclopentadienetrialkylamine and benzenetrialkylamine.

In some embodiments, the first organic precursor is an aromatic diamine. In some embodiments, the aromatic diamine is a diaminobenzene, such as 1,2-diaminobenzene, 1,3-diaminobenzene or 1,4-diaminobenzene. In some embodiments, the aromatic diamine comprises an alkylamino group in at least one position. For example, the alkylamino group may be a C1 to C3 alkylamino group, such as —CH₂NH₂, —(CH₂)₂NH₂, —(CH₂)₃NH₂, —CH(CH₃)NH₂ or —CH₂CH(CH₃)NH₂.

In some embodiments, the first organic precursor is selected from a group consisting of 1,3-diaminopentane, 1,4-diaminopentane, 2,4-diaminopentane, 2,4-diamino-2,4-dimethylpentane, 1,5-diamino-2-methylpentane, 1,3-diaminobutane, 1,3-diamino-3-methylbutane, 2,5-diamino-2,5-dimethylhexane, 1,4-diamino-4-methylpentane, 1,3-diaminobutane, 1,5-diaminohexane, 1,3-diaminohexane, 2,5-diaminohexane, 1,3-diamino-5-methylhexane, 4,4,4-trifluoro-1,3-diamino-3-methylbutane, 2,4-diamino-2-methylpentane, 4-(1-methylethyl)-1,5-diaminohexane, 3-aminobutanamide, 1,3-diamino-2-ethylhexane, 2,7-diamino-2,7-dimethyloctane, 1,3-diaminobenzene and 1,4-diaminobenzene. In some embodiments, the first organic precursor comprises a halogen.

In some embodiments, triamines may be used in the deposition of organic polymer according to the current invention. Providing such molecules may advantageously affect the availability of polymerization sites for the second vapor-phase organic precursor. The availability of three amine groups in a single molecule, may lead to denser polymer network, which again may reduce the metal migration through the organic polymer. Such properties may be advantageous in embodiments utilizing the organic polymer according to the current disclosure as a passivation layer. Examples of suitable triamines include 1,2,3-triaminopropane, triamino butane (with amines in carbons 1, 2 and 3 or in carbons 1, 2 and 4), triamino pentane (especially with amines in carbons 1 and 5, plus in any one of the carbons 2, 3 or 4). Similarly, triamino hexanes may contain amine groups in carbons 1 and 6, as well as in any one of the positions 2, 3, 4 or 5; triamino heptanes may contain amine groups in carbons 1 and 7, as well as in any one of the positions 2, 3, 4, 5 or 6; and triamino octanes may contain amine groups in carbons 1 and 8, as well as in any one of the positions 2, 3, 4, 5, 6 or 7. Further, branched carbon chains, notably 2-aminomethyl-1,3-diaminopropane, 2-aminomethyl-1,4-diaminobutane (or alternatives having the two amino groups elsewhere in the butane chain), 2-aminomethyl-1,5-diaminopentane (or alternatives having the two amino groups elsewhere in the pentane chain), 3-aminomethyl-1,5-diaminopentane (or alternatives having the two amino groups elsewhere in the pentane chain), 2-aminomethyl-1,6-diaminohexane (or alternatives having the two amino groups elsewhere in the hexane chain), 3-aminomethyl-1,6-diaminohexane (or alternatives having the two amino groups elsewhere in the hexane chain), 3-aminoethyl-1,6-diaminohexane (or alternatives having the two amino groups elsewhere in the hexane chain). Also, an aromatic triamine, such as 1,3,5-triaminobenzene, may be an alternative for certain embodiments.

In some embodiments, the second vapor-phase organic precursor comprises pyromellitic dianhydride (PMDA).

In some embodiments, the polymer deposited comprises polyimide. Thus, in some embodiments, the organic polymer comprises polyimide. In some embodiments, the organic polymer consists substantially only of polyimide. In some embodiments, the organic polymer comprises polyamic acid. In some embodiments, the organic polymer consists substantially only of polyamic acid and polyimide. In some embodiments, the organic polymer is deposited at temperatures below 190° C., and subsequently heat-treated (annealed) at a temperature of about 190° C. or higher (such as from about 200° C. to about 500° C.) to increase the proportion of the organic polymer from polyamic acid to polyimide. Other examples of deposited polymers include dimers, trimers, polyurethanes, polythioureas, polyesters, polyimines, other polymeric forms or mixtures of the above materials.

In some embodiments the substrate is thermally annealed for a period of about 1 to about 15 minutes. In some embodiments the substrate is thermally annealed at a temperature of about 200 to about 500° C. In some embodiments the thermal anneal step comprises two or more steps in which the substrate is thermally annealed for a first period of time at a first temperature and then thermally annealed for a second period of time at a second temperature.

In some embodiments, the deposited organic polymer is exposed to reactive species generated from plasma. This may improve the passivation properties of the organic polymer in embodiments in which it is used as a passivation material. For example, reactive species generated from hydrogen- and argon-comprising plasma can be used. The organic polymer may be exposed to plasma from about 1 seconds to about 1 minute, such as from about 1 second to about 30 seconds, or from about 5 seconds to about 30 seconds, or for about 1 second to about 15 seconds, or from about 3 seconds to about 20 seconds, for example for about 5 seconds, for about 10 seconds, for about 20 seconds or for about 30 seconds. A plasma power of at least about 20 W, or at least about 50 W, such as from about 20 W to about 100 W, such as 30 W, 50 W or 70 W, may be used. The suitable plasma power and duration of the plasma exposure may be determined experimentally.

In some embodiments, alternatively or in addition to the plasma treatment aimed at amending the properties of the organic polymer, a plasma treatment may be used to at least partially remove inhibitor material from the first surface. In such embodiments, higher plasma energy is typically used, which may negatively affect the passivation properties of the organic polymer, for example, through removal of the organic polymer from the second surface. The inhibitor reactants according to the current disclosure may have the advantage of requiring less of removing than alternative inhibitor reactants. This may be beneficial, as the damage to the organic polymer—and possibly to other surfaces exposed to plasma—may be reduced. This may improve the selectivity of the subsequent deposition steps. Further, the inhibitor reactants according to the current disclosure may allow the growth of target material after shorter plasma exposure than conventional inhibitor reactants and inhibitor materials deposited using them.

Additional treatments, such as heat or chemical treatment, can be conducted prior to, after or between the processing steps described herein. For example, treatments may modify the surfaces or remove portions of the material on the substrate surfaces exposed at various stages of the process. In some embodiments, the substrate may be pretreated or cleaned prior to or at the beginning of the selective deposition of organic polymer. In some embodiments, the substrate may be subjected to a plasma cleaning process at prior to or at the beginning of the selective deposition of organic polymer. In some embodiments, a plasma cleaning process may not include ion bombardment, or may include relatively small amounts of ion bombardment. For example, in some embodiments the substrate surface may be exposed to plasma, radicals, excited species, and/or atomic species prior to or at the beginning of the selective deposition of organic polymer. In some embodiments, the substrate surface may be exposed to hydrogen plasma, radicals, or atomic species prior to or at the beginning of the selective deposition of organic polymer. In some embodiments, a pretreatment or cleaning process may be carried out in the same reaction chamber as a selective deposition of organic polymer 210, however in some embodiments a pretreatment or cleaning process may be carried out in a separate reaction chamber. Further, deposition of inhibitor material 204, 206 and deposition of an organic polymer 210 may be performed in the same reaction chamber, or in separate reaction chambers of the same cluster tool. The deposition of inhibitor material 204, 206 and deposition of an organic polymer 210 may be performed in the same deposition station, or in separate deposition stations of a multi-station chamber.

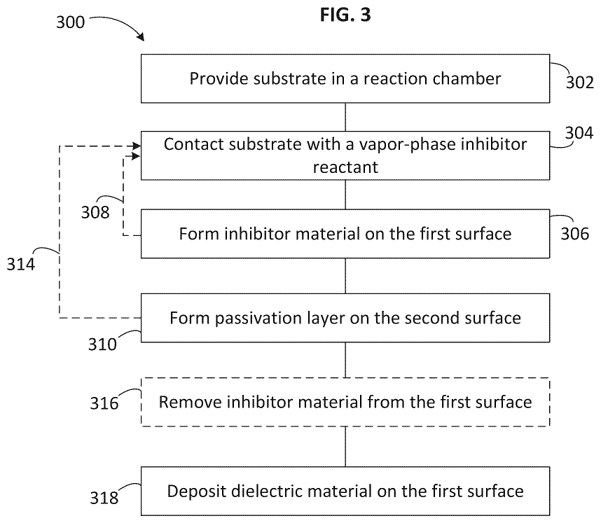

FIG. 3 is a block diagram of a further exemplary embodiment of a method according to the current disclosure 300.

In the method 300 of FIG. 3, blocks 302, 304, 306 and 308 are performed as described of the corresponding blocks 102, 104, 106 and 108 for the embodiment of FIG. 1 and blocks 202, 204, 206 and 208 for the embodiment of FIG. 2.

Loop 308 corresponds to loops 108 and 208 of FIGS. 1 and 2, respectively and indicates that the deposition of inhibition material may be repeated after initially passivating the first surface against deposition of organic polymer. Similarly, the optional loop 314 corresponds to loop 214 of FIG. 2 and indicates, that the deposition of inhibitor material may be renewed during the selective deposition process of the organic polymer 310. In embodiments, in which a target material is deposited on the first surface 318, the deposition of inhibitor material 304, 306 may be renewed after some deposition of a passivation layer comprising organic polymer, optional loop 314.

The embodiments depicted in in FIG. 3 correspond to depositing the target material on the first surface 318. The deposition of the target material on the first surface comprises depositing a passivation layer on the second surface 310. The passivation layer may be an organic polymer layer as explained for FIG. 2. Optionally, the deposition of a target material on the first surface may comprise at least partial removal of the inhibitor material from the first surface 316 before depositing the target material on the first surface 318.

The selective deposition process of the target material 318 according to the current disclosure may be a cyclic deposition process, such as an ALD process. For example, target material deposited at stage 318 may be aluminum oxide, silicon oxide, aluminum-doped silicon oxide, yttrium oxide or metal nitrides, such as TiN or TaN.

For example, the deposition 318, may be performed by, for example, providing a metal (Al, Mo, Ti, Ta, Y) or a semimetal (such as Si) precursor into the reaction chamber and a second precursor into the reaction chamber alternately and sequentially. The second precursor may be an oxygen precursor, or a nitrogen precursor, or a reducing agent, for example. The reaction chamber may optionally be purged after one or both precursors. Various cycling options, including master cycle alternatives, are known in the art, and additional metal or other precursors may be utilized in the process to adjust the composition of the target material. The deposition cycle (comprising a metal or a semimetal precursor pulse and an second precursor pulse) may be performed from 1 to about 1,000 times, such as from 2 to 800 times, or from about 5 to about 500 times, or from about 10 to about 500 times, or from about 20 to about 500 times, or from about 50 to about 500 times, or from about 100 to about 500 times, or from about 250 to about 500 times, or from 2 to about 250 times, or from about 2 to about 150 times, or from about 2 to about 100 times, or from about 2 to about 75 times, or from about 2 to about 50 times, or from about 2 to about 30 times, or from about 2 to about 10 times. The number of deposition cycles may be determined experimentally, depending on the desired thickness and other properties of the target material.

An example of a target material that may be deposited according to the methods disclosed herein is aluminum oxide. It can be deposited selectively using dimethylaluminum isopropoxide as aluminum precursor and water as oxygen precursor. Aluminum oxide deposition is selective against surfaces comprising an organic passivation, such as polyimide-comprising passivation. Aluminum oxide may be deposited on silicon oxide-based materials relative to a metal surface. In the various tests performed, it was observed that using inhibitor materials according to the current disclosure, the growth delay of aluminum oxide was significantly reduced compared to prior art inhibitor reactants. Therefore, it is possible to grow a metal-containing material on the first surface without removing the inhibitor material. Further, a hydrogen-containing plasma was used to clean the substrate after depositing the organic passivation material on the second surface. It was further observed that the duration of the plasma treatment could be significantly reduced using inhibitor reactants disclosed herein, possibly leading to improved process performance and/or efficiency.

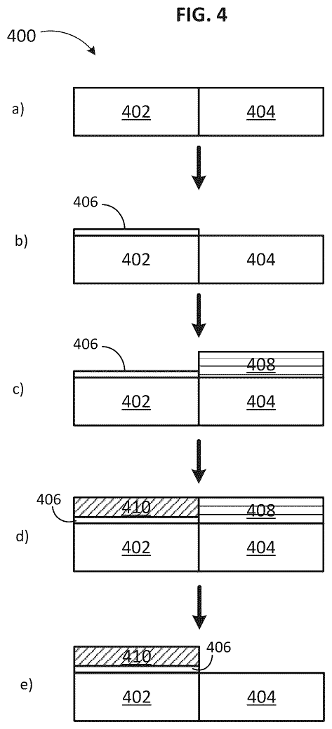

FIG. 4 is a schematic presentation of exemplary embodiments of a method according to the current disclosure. FIG. 4, panels a) to e) illustrates an embodiment of a method according to the current disclosure schematically. In the panel a), a substrate 400 comprising a first surface 402 and a second surface 404 is depicted. In panel b) an inhibitor material 406 according to the current disclosure is deposited on the first surface 402 relative to the second surface 404. In panel c) the second surface 404 is selectively passivated by an organic passivation layer 408 relative to the first surface 402 comprising the inhibitor layer 406. In panel d) selective deposition of a target material, such as a layer of a metal-containing material 410 on the first surface 402 relative to the passivated second surface 404 is performed.

More specifically, panel a) illustrates a substrate 400 having two surfaces 402, 404 having different material properties. The first surface 404 may comprise, consist essentially of, or consist of silicon oxide-based material or another dielectric material, such as silicon-based material described in this disclosure. The second surface 402 may comprise, consist essentially of, or consist of a metal, such as Cu, W or Mo, or a metallic material, such as TiN as disclosed herein.

Panel b) shows the substrate 400 of panel a) after depositing an inhibition layer the first surface 402. Although depicted in FIG. 4 as a layer, the inhibitor material of the first surface 402 may be very thin. Panel c) shows the substrate 400 of panel b) after selective deposition of an organic passivation layer 408 on the second surface 404, such as by formation of a polyimide-comprising layer.

Panel d) shows the substrate 400 of panel c) following selective deposition of a target material layer 410, such as a metal oxide layer or a metal nitride layer, on the first surface 402 relative to the passivated second surface 404 according to the methods disclosed herein. Any target material 410 deposited on the second surface 404, such as on the passivation layer 408, can be removed by a treatment, such as an etch-back process. However, this may be challenging for some materials, due to their high etch resistivity. Therefore, in many embodiments, etch back is not performed, but the selectivity of the process is high enough without it. In other embodiments, target material over the second surface 404 may be removed during subsequent removal of the passivation layer 408. In some embodiments, etching is used as a post-deposition process to clean up the final surfaces, and/or to remove passivation.

The inhibitor material 406 is visible in panel d). In some embodiments, however, the inhibitor material 406 may be removed before depositing the target material 410 on the first surface 402. That may be desired, for example in embodiments in which the first surface 402 and the second surface 404 are in the same orientation, as is the case in the depicted example. However, FIG. 4 is illustrative of embodiments, in which the first surface and the second surface may be in a different orientation, such as at an angle, for example perpendicular, relative to each other. In such embodiments, efficient plasma cleaning of surfaces positioned in the direction of the plasma flow may be challenging, and the current methods may be advantageous. In further embodiments, the inhibitor material may be partially removed by a plasma cleaning. The choice of the process flow depends on factors such as the application in question, the deposited material, and requirements of the material stack, and can be adjusted according to such considerations.

Panel e) shows the substrate of panel d) after a post-deposition treatment to remove the passivation layer 408 from the second surface 404, such as by an etch process. In some embodiments, the etch process may comprise exposing the substrate 400 to a plasma. In some embodiments, the plasma may comprise oxygen atoms, oxygen radicals, oxygen plasma, or combinations thereof. In some embodiments, the plasma may comprise hydrogen atoms, hydrogen radicals, hydrogen plasma, or combinations thereof. In some embodiments, the plasma may comprise noble gas species, for example Ar or He species. In some embodiments, the plasma may consist essentially of noble gas species. In some embodiments, the plasma may comprise other species, for example nitrogen atoms, nitrogen radicals, nitrogen plasma, or combinations thereof. In some embodiments, the etch process may comprise exposing the substrate to an etchant comprising oxygen, for example O₃. In some embodiments, the substrate may be exposed to an etchant at a temperature of between about 30° C. and about 500° C., or between about 100° C. and about 400° C., or between about 100° C. and about 300° C. In some embodiments, the etchant may be supplied in one continuous pulse or may be supplied in multiple pulses. The removal of the passivation layer 408 can be used to lift-off any remaining target material from over the second surface, either in a complete removal of the passivation layer 108 or in a partial removal of the passivation layer 508 in a cyclical selective deposition and removal.

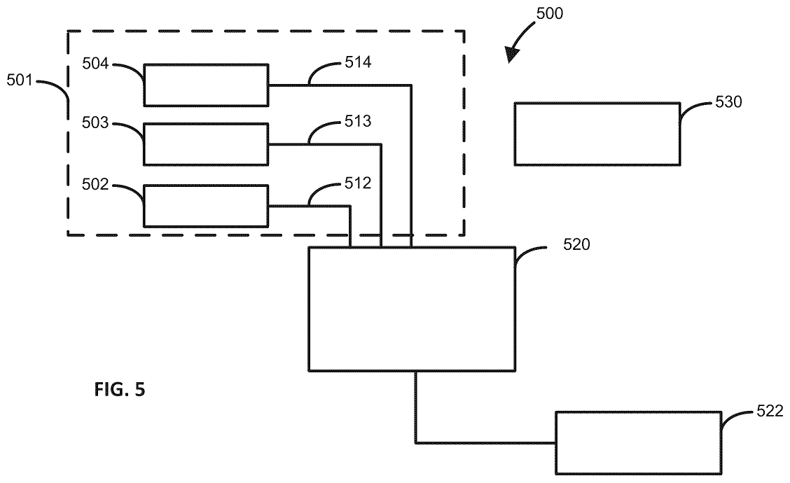

FIG. 5 is a schematic drawing of an embodiment of a semiconductor processing assembly 500 according to the current disclosure.

In yet another aspect, a semiconductor processing assembly 500 for selectively depositing an inhibitor material on a first surface of a substrate is disclosed. The semiconductor processing assembly 500 comprises one or more reaction chambers 520 constructed and arranged to hold the substrate, a precursor injector system 501 constructed and arranged to provide an inhibitor reactant into the reaction chamber 520 in a vapor phase. The semiconductor processing assembly 500 further comprises an inhibitor reactant source vessel 502 constructed and arranged to contain the inhibitor reactant. The semiconductor processing assembly 500 is constructed and arranged to provide the inhibitor reactant via the precursor injector system 501 into the reaction chamber 520 for selectively forming inhibitor material on the first surface of the substrate.

In some embodiments, the semiconductor processing assembly 500 further comprises one or more precursor source vessels 503, 504, and the precursor injector system 501 is constructed and arranged to provide the one more precursor into the reaction chamber 520 in a vapor phase. The precursors may be organic precursors for depositing a passivation layer on the second surface of the substrate. Alternatively or in addition, the precursors may be metal precursors, semimetal precursors, oxygen precursors, nitrogen precursors or other precursors for depositing target material on the first surface of the substrate.

The processing assembly 500 may comprise optional further source vessels constructed and arranged to contain additional reactants used in the processing of the substrate. For example, a further source vessel (not depicted) may be constructed and arranged to hold an etchant.

The processing assembly 500 can be used to perform a method as described herein. In the illustrated example, processing assembly 500 includes one or more reaction chambers 520, a precursor injector system 501, source vessels 502, 503, 504, optional and further source vessels, an exhaust source 522, and a controller 530. The processing assembly 500 may comprise one or more additional gas sources (not shown), such as an inert gas source, a carrier gas source and/or a purge gas source. Reaction chamber 520 can include any suitable reaction chamber, such as an ALD or CVD reaction chamber as described herein.

The inhibitor reactant source vessel 502 can include a vessel and an inhibitor reactant as described herein—alone or mixed with one or more carrier (e.g., inert) gases. Thus, although illustrated with three source vessels 502-504, a processing assembly 500 can include any suitable number of source vessels. Source vessels 502-504 can be coupled to reaction chamber 520 via lines 512-514, which can each include flow controllers, valves, heaters, and the like. In some embodiments, each of the source vessels 502-504 may be independently heated or kept at ambient temperature. In some embodiments, a source vessel is heated so that a precursor or a reactant reaches a suitable temperature for vaporization

Exhaust source 522 can include one or more vacuum pumps.

Controller 530 includes electronic circuitry and software to selectively operate valves, manifolds, heaters, pumps and other components included in the processing assembly 500. Such circuitry and components operate to introduce precursors, reactants and other gases from the respective sources. Controller 530 can control timing of gas pulse sequences, temperature of the substrate and/or reaction chamber 520, pressure within the reaction chamber 520, and various other operations to provide proper operation of the processing assembly 500. Controller 530 can include control software to electrically or pneumatically control valves to control flow of precursors, reactants and other gases into and out of the reaction chamber 520. Controller 530 can include modules such as a software or hardware component, which performs certain tasks.

Other configurations of processing assembly 500 are possible, including different numbers and kinds of precursor and source vessels. For example, a reaction chamber 520 may comprise more than one, such as two or four, deposition stations. Such a multi-station configuration may have advantages if, for example, inhibition, passivation, deposition and/or etching are to be performed in the same reaction chamber. Further, it will be appreciated that there are many arrangements of valves, conduits, precursor sources, and reactant sources that may be used to accomplish the goal of selectively and in coordinated manner feeding gases into reaction chamber 520. Further, as a schematic representation of a processing assembly 500, many components have been omitted for simplicity of illustration, and such components may include, for example, various valves, manifolds, purifiers, heaters, containers, vents, and/or bypasses.

During operation of processing assembly 500, substrates, such as semiconductor wafers (not illustrated), are transferred from, e.g., a substrate handling system to reaction chamber 520. Once substrate(s) are transferred to reaction chamber 520 (i.e. they are provided in the reaction chamber 520), one or more gases from gas sources, such as precursors, reactants, carrier gases, and/or purge gases, are introduced into reaction chamber 520.

The example embodiments of the disclosure described above do not limit the scope of the disclosure, since these embodiments are merely examples of the embodiments of the methods, structures, devices and processing assemblies, which are defined by the appended claims and their legal equivalents. Any equivalent embodiments are intended to be within the scope of this disclosure. Various modifications of the disclosure, in addition to those shown and described herein, such as alternative useful combinations of the elements described, may become apparent to those skilled in the art from the description. Such modifications and embodiments are also intended to fall within the scope of the appended claims.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject-matter of the present disclosure includes all novel and nonobvious combinations and sub-combinations of the various methods and assemblies, and other features, functions, acts, and/or properties disclosed herein, as well as any and all equivalents thereof.

1. A method of selectively depositing inhibitor material on a first surface of a substrate relative to a second surface of the substrate, the method comprising
providing the substrate comprising the first surface and the second surface in a reaction chamber;
contacting the substrate with a vapor-phase inhibitor reactant, the inhibitor reactant comprising a silicon atom bonded to a first atom and to a second atom;
wherein the first atom is oxygen, and the second atom is selected from nitrogen and a halogen; and
wherein the inhibitor reactant selectively forms inhibitor material on the first surface.

2. The method of claim 1, wherein the first surface comprises dielectric material.

3. The method of claim 1, wherein the first surface comprises material selected from a group consisting of SiO₂, SiN, SiC, SiOC, SiON, SiOCN, SiGe and combinations thereof.

4. The method of claim 2, wherein the dielectric material comprises a metal oxide or a metal nitride.

5. The method of claim 2, wherein the dielectric material is selected from aluminum oxide, hafnium oxide, zirconium oxide, aluminum nitride, tantalum nitride and combinations thereof.

6. The method of claim 1, wherein the second surface comprises a material selected from a group consisting of a metal, amorphous carbon, metal oxide and metal nitride.

7. The method of claim 1, wherein the second surface comprises a metal selected from a group consisting of Ti, V, Nb, Ta, Cr, Mo, W, Mn, Fe, Co, Ni, Cu, Zn, Ru and Al.

8. The method of claim 1, wherein the second surface comprises elemental metal.

9. The method of claim 1, wherein the first atom is oxygen of an alkoxy group.

10. The method of claim 1, wherein the silicon atom is bonded to at least two oxygen atoms, and each oxygen atom is an oxygen of an alkoxy group.

11. The method of claim 1, wherein the second atom is a nitrogen atom of an amine group.

12. The method of claim 11, wherein the amine group is a tertiary amine.

13. The method of claim 1, wherein the second atom is a halogen selected from a group consisting of F, Cl, Br and I.

14. The method of claim 1, wherein the inhibitor reactant is represented by a formula Si(OR)ₐX_{b}R′_{c}, wherein
each R is independently selected from linear, branched and cyclic C1 to C6 alkyls and phenyl;
each R′ is independently selected from H, linear, branched and cyclic C1 to C6 alkyls and phenyl;
X is selected from halogens or NR′₂, and
a is 1, 2 or 3; b is 1 or 2; c is 0, 1 or 2; and a+b+c=4.

15. The method of claim 14, wherein all R and R′ are C1 to C4 alkyls.

16. The method of claim 1, wherein the inhibitor reactant is selected from a group consisting of Si(OMet)₃Cl, Si(OMet)₃Br, Si(OMet)₃I, Si(OMet)₂Cl₂, Si(OMet)₂Br₂, Si(OMet)₂I₂, Si(OEt)₃Cl, Si(OEt)₃Br, Si(OEt)₃I, Si(OEt)₂Cl₂, Si(OEt)₂Br₂, Si(OEt)₂I₂, Si(OMet)₃(NH₂), Si(OMet)₂(NH₂)₂, Si(OEt)₃(NH₂), Si(OEt)₂(NH₂)₂, Si(OMet)₃(NMet₂), Si(OMet)₂(NMet₂)₂, Si(OEt)₃(NMet₂), Si(OEt)₂(NMet₂)₂, Si(OMet)₃(NMetH), Si(OMet)₂(NMetH)₂, Si(OEt)₃(NMetH), Si(OEt)₂(NMetH)₂, Si(OMet)₃(NEt₂), Si(OMet)₂(NEt₂)₂, Si(OEt)₃(NEt₂) and Si(OEt)₂(NEt₂)₂.

17. The method of claim 1, wherein the deposition is performed at a temperature of below 400° C.

18. The method of claim 1, wherein the inhibitor material is deposited substantially only on the first surface and not on the second surface.

19. A method of selectively depositing a target material on a first surface of a substrate, the method comprising selectively depositing inhibitor material on the first surface of the substrate according to claim 1 before depositing the target material.

20. The method of claim 19, wherein the method further comprises depositing a passivation layer on the second surface of the substrate after selectively depositing inhibitor material on the first surface, and thereafter depositing the target material on the first surface.

21. The method of claim 19, wherein the inhibitor material is not removed before depositing the target material on the first surface.

22. A method of depositing silicon-containing material on a substrate; the method comprising
providing the substrate in a reaction chamber;
contacting the substrate with a vapor-phase silicon reactant having a formula Si(OR)ₐX_{b}R′_{c}, wherein
each R is independently selected from linear, branched and cyclic C1 to C6 alkyls and phenyl;
each R′ is independently selected from H, linear, branched and cyclic C1 to C6 alkyls and phenyl;
X is selected from NR′₂; and
a is 1, 2 or 3; b is 1 or 2; c is 0, 1 or 2; and a+b+c=4,
wherein the silicon reactant forms silicon-containing material on a surface of the substrate.

23. The method of claim 22, wherein the silicon-containing material has a silicon to oxygen ratio from about 1:1 to 1:3.
